(19) United States
(12) Patent Application Publication
(10) Pub. No.: US 2025/0268086 A1
(43) Pub. Date: Aug. 21, 2025

(54) DISPLAY APPARATUS

(71) Applicant: LG Display Co., Ltd., Seoul (KR)

(72) Inventors: Yongmin KIM, Paju-si (KR); JungSun BAEK, Paju-si (KR); Yooji HWANG, Paju-si (KR)

(73) Assignee: LG Display Co., Ltd., Seoul (KR)

(21) Appl. No.: 18/968,282

(22) Filed: Dec. 4, 2024

(30) Foreign Application Priority Data
Feb. 19, 2024 (KR) 10-2024-0023454

(51) Int. Cl. H10K 59/80; H10K 59/122

(52) U.S. Cl. CPC H10K 59/8792; H10K 59/122; H10K 59/873; H10K 59/879

(57) ABSTRACT

A display device may include: an insulating layer disposed on a substrate; structures that are spaced apart from each other, are disposed on the insulating layer, and include an insulating material; a pixel electrode that is disposed on the insulating layer and on at least one or more parts of the structures; and viewing angle adjustment patterns that are spaced apart from each other and are disposed above the structures. The viewing angle adjustment patterns may extend in a first direction, and the structures may extend in a second direction. The viewing angle adjustment patterns may reduce, in one direction, a viewing angle of light emitted from an emission layer. The structures may widen, in another direction, a viewing angle of light emitted from the emission layer. The viewing angle in the another direction may be greater than the viewing angle in the one direction.

### CROSS-REFERENCE TO RELATED APPLICATIONS

This application claims the benefit of and priority to Korea Patent Application No. 10-2024-0023454, filed on Feb. 19, 2024, the entire contents of which are incorporated herein by reference for all purposes, as if fully set forth herein.

### BACKGROUND

### 1. Technical Field

The present disclosure relates to electronic devices, and more specifically, to display devices.

### 2. Description of the Related Art

With the advent of the information society, the demand for display devices for displaying images has steadily increased. To meet such demand, various types of display devices, such as liquid crystal display (LCD) devices, organic light emitting display (OLED) devices, inorganic light emitting display (iLED) devices, micro-light emitting display (micro LED) devices, mini-light emitting display (mini LED) devices, quantum dot light emitting display (QLED) devices, and the like, have been developed.

Display devices can have a structure of enabling light emitted from light emitting elements to move out of the display devices for displaying images. The display devices have suffered from a problem in which luminance of the display devices is reduced due to a situation where light emitted from light emitting elements is trapped inside of the display devices without moving out, and the like. Challenges can arise in improving the luminance of display devices.

In addition, there is a need for display devices capable of adjusting a viewing angle according to a viewing direction in which a user views the screen, and maintaining excellent luminance.

The description of the related art should not be assumed to be prior art merely because it is mentioned in or associated with this section. The description of the related art includes information that describes one or more aspects of the subject technology, and the description in this section does not limit the invention.

### SUMMARY

One or more aspects of the present disclosure may provide a display device capable of improving light extraction efficiency.

One or more aspects of the present disclosure may provide a display device capable of adjusting a viewing angle according to a viewing direction in which a user views the screen, and improving luminance.

One or more aspects of the present disclosure may provide a display device capable of being driven with low power by improving light extraction efficiency, adjusting a viewing angle according to a viewing direction, and improving luminance.

According to one or more aspects of the present disclosure, a display device may be provided that includes structures in one direction and viewing angle adjustment patterns, and thereby, is capable of improving light extraction efficiency.

According to one or more aspects of the present disclosure, a display device may be provided that includes structures in one direction and viewing angle adjustment patterns, and thereby, is capable of adjusting a viewing angle according to a viewing direction and improving luminance.

According to one or more aspects of the present disclosure, a display device may be provided that is capable of being driven with low power by improving light extraction efficiency, adjusting a viewing angle according to a viewing direction, and improving luminance.

According to one or more aspects of the present disclosure, a display device may comprise: a substrate; an insulating layer disposed on the substrate; a plurality of structures that are spaced apart from each other, are disposed on the insulating layer, and include an insulating material; a pixel electrode that is disposed on the insulating layer and on at least one or more parts of the plurality of structures; and a plurality of viewing angle adjustment patterns that are spaced apart from each other and are disposed above the plurality of structures. The plurality of viewing angle adjustment patterns may extend in a first direction, and the plurality of structures may extend in a second direction different from the first direction.

According to one or more aspects of the present disclosure, a display device may comprise: a light emitting area; one or more structures that are disposed adjacent to the light emitting area, and are configured to adjust a viewing angle of light emitted from an emission layer; and one or more viewing angle adjustment patterns that are disposed above the one or more structures and are configured to adjust a viewing angle of light emitted from the emission layer.

According to one or more aspects of the present disclosure, a display device may comprise: a light emitting area; one or more structures that are disposed adjacent to the light emitting area, only partially surround the light emitting area, and extend in a direction; and a pixel electrode that is disposed at the light emitting area and on at least one or more inclined surfaces of the one or more structures. In one or more examples, the pixel electrode disposed on the at least one or more inclined surfaces may be configured to adjust a viewing angle of light emitted from an emission layer.

According to one or more aspects of the present disclosure, a display device may comprise: a light emitting area; an emission layer that is disposed at the light emitting area; and one or more viewing angle adjustment patterns that are disposed above the emission layer and are configured to adjust a viewing angle of light emitted from the emission layer.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 illustrates an example system configuration of a display device according to one or more aspects of the present disclosure;

FIG. 2 illustrates an example display panel according to one or more aspects of the present disclosure;

FIG. 3 illustrates an example vehicle equipped with the display device according to one or more aspects of the present disclosure;

FIG. 4 is an example plan view illustrating subpixels disposed in an active area in the display device according to one or more aspects of the present disclosure;

FIG. 5 is a perspective view illustrating an example portion of the display device according to one or more aspects of the present disclosure;

FIG. 6 is an example cross-sectional view taken along line A-A′ of FIG. 4 according to one or more aspects of the present disclosure;

FIG. 7 is an example cross-sectional view taken along line B-B′ of FIG. 4 according to one or more aspects of the present disclosure;

FIG. 8 is a perspective view illustrating another example portion of the display device according to one or more aspects of the present disclosure;

FIG. 9 is another example cross-sectional view taken along line A-A′ of FIG. 4 according to one or more aspects of the present disclosure;

FIG. 10 is another example cross-sectional view taken along line B-B′ of FIG. 4 according to one or more aspects of the present disclosure;

FIG. 11 is another example plan view illustrating subpixels disposed in the active area in the display device according to one or more aspects of the present disclosure;

FIG. 12 is an example plan view illustrating a subpixel disposed in the active area in the display device according to one or more aspects of the present disclosure;

FIG. 13 is an example cross-sectional view taken along line C-C′ of FIG. 12 according to one or more aspects of the present disclosure;

FIG. 14 is an example cross-sectional view taken along line D-D′ of FIG. 12 according to one or more aspects of the present disclosure;

FIG. 15 is an example cross-sectional view taken along line E-E′ of FIG. 12 according to one or more aspects of the present disclosure; and

FIGS. 16 to 18 are example plan views illustrating subpixels disposed in the active area in the display device according to one or more aspects of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure. Further, the present disclosure is defined by the scope of claims and their equivalents.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, patterns, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, patterns, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “left,” “right,” “a left portion,” “a right portion,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, patterns, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, pattern, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like (or the terms such as one direction, another direction, a row direction, a column direction, a diagonal direction, a horizontal direction, a vertical direction, a left-right direction, or an up-down direction) should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” “at least one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

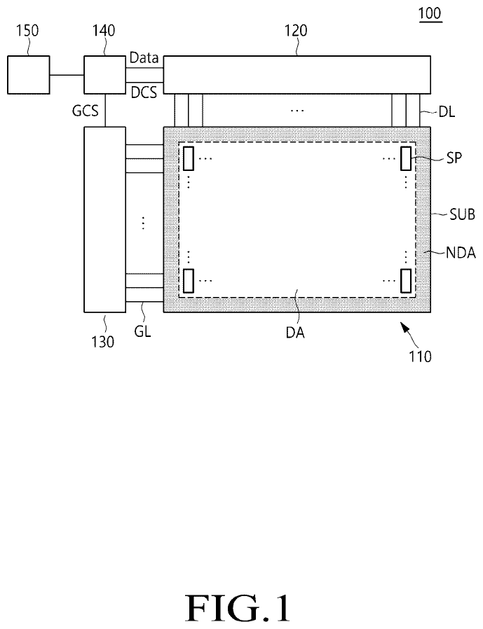

FIG. 1 illustrates an example system configuration of a display device 100 according to one or more aspects of the present disclosure. All components of each display device according to all aspects of the present disclosure are operatively coupled and configured.

Referring to FIG. 1, in one or more aspects, the display device 100 may include a display panel 110 and a display driving circuit, as elements configured to display images. The display driving circuit may be a circuit configured to drive the display panel 110, and include a data driving circuit 120, a gate driving circuit 130, a controller 140, and other circuit components.

The display panel 110 may include a substrate SUB and a plurality of subpixels SP disposed on the substrate SUB.

The substrate SUB may include an active area AA allowing an image to be displayed and a non-active area NA located outside of the active area AA.

The active area AA may also be referred to as a display area DA, and a plurality of subpixels SP for displaying images may be disposed at the active area AA. The non-active area NA may also be referred to as a non-display area NDA and may include a pad area PA, and the like. For example, the pad area PA may be a portion of the non-active area NA disposed in a first direction (e.g., a column direction or a row direction) from the active area AA.

In one or more aspects, the display panel 110 may be configured to have a very small non-active area NA. Herein, the non-active area NA may also be referred to as “bezel.” For example, the non-active area NA may include a first non-active area disposed outside of the active area AA in a first direction, a second non-active area disposed outside of the active area AA in a second direction, a third non-active area disposed outside of the active area AA in a direction opposite to the first direction, and a fourth non-active area disposed outside of the active area AA in a direction opposite to the second direction. The first non-active area among the first to fourth non-active areas may include a pad area to which at least one driving circuit is connected or bonded. Among the first to fourth non-active areas, the second to fourth non-active areas, which do not include a pad area, may have a very small size compared to the first non-active area.

In another example, the non-active area NA may be bent along a boundary between the active area AA and the non-active area NA at a certain angle to the active area AA, and thereby, be located under the active area AA. In this implementation, when a user views the display device 100 in front thereof, all or most of the non-active area NA may not be visible to the user. But aspects of the present disclosure are not limited thereto.

Various types of signal lines for driving a plurality of subpixels SP may be disposed on the substrate SUB of the display panel 110.

In one or more aspects, the display device 100 herein may be a liquid crystal display device, or the like, or a self-emission display device in which light is emitted from the display panel 110 itself. In an example where the display device 100 is the self-emission display device, each of the plurality of subpixels SP may include a light emitting element.

For example, the display device 100 according to one or more aspects of the present disclosure may be an organic light emitting display device in which light emitting elements are implemented using organic light emitting diodes (OLED). In another example, the display device 100 according to one or more aspects of the present disclosure may be an inorganic light emitting display device in which light emitting elements are implemented using inorganic material-based light emitting diodes. In further another example, the display device 100 according to one or more aspects of the present disclosure may be a quantum dot display device in which light emitting elements are implemented using quantum dots, which are self-emission semiconductor crystals.

The structure of each of the plurality of subpixels SP may depend on types of display device 100. In an example where the display device 100 is a self-emission display device including self-emission subpixels SP, each subpixel SP may include a self-emission light emitting element, one or more transistors, and one or more capacitors.

The various types of signal lines may include, for example, a plurality of data lines DL for carrying data signals (which may be referred to as data voltages or image signals), a plurality of gate lines GL for carrying gate signals (which may be referred to as scan signals), and the like.

In one or more aspects, the plurality of gate lines GL and the plurality of data lines DL may intersect one another. Each of the plurality of gate lines GL may be configured to extend in a first direction, and each of the plurality of data lines DL may be configured to extend in a second direction. For example, the first direction may be a row or horizontal direction, and the second direction may be a column or vertical direction. In another example, the first direction may be the column or vertical direction, and the second direction may be the row or horizontal direction. Hereinafter, for convenience of explanation, discussions are provided based on examples where each of the plurality of gate lines GL is disposed in the row direction and each of the plurality of data lines DL is disposed in the column direction, but aspects of the present disclosure are not limited thereto.

The data driving circuit 120 may be a circuit for driving a plurality of data lines DL and can output data signals to the plurality of data lines DL.

The data driving circuit 120 can receive image data DATA in a digital form from the controller 140, and convert the received image data DATA into data signals in an analog form, and output the converted data signals to the plurality of data lines DL.

In some aspects, the data driving circuit 120 may be connected to the display panel 110 by a tape-automated-bonding (TAB) technology, or connected to a conductive pad such as a bonding pad of the display panel 110 by a chip-on-glass (COG) technology or a chip-on-panel (COP) technology, or connected to the display panel 110 by a chip-on-film (COF) technology. However, aspects of the present disclosure are not limited thereto.

The data driving circuit 120 may be disposed in, and/or electrically connected to, but not limited to, only one side or edge (e.g., an upper portion or a lower portion) of the display panel 110. In some aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to outside of the active area AA of the display panel 110, or be disposed in the active area AA of the display panel 110.

The gate driving circuit 130 may be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In some aspects, the gate driving circuit 130 in the display device 100 may be embedded into the display panel 110 by a gate-in-panel (GIP) technology. In an example where the gate driving circuit 130 is implemented by the gate-in-panel (GIP) technology, the gate driving circuit 130 may be disposed on the substrate SUB of the display panel 110 during the process of manufacturing the display panel 110.

In one aspect, the gate driving circuit 130 may be disposed in the non-active area NA of the display panel 110.

In another aspect, the gate driving circuit 130 may be disposed in the active area AA of the display panel 110. In this implementation, for example, the gate driving circuit 130 may be disposed in, and/or electrically connected to, but not limited to, a portion of a first area (e.g., a left area or a right area) of the active area AA of the display panel 110. In another example, the gate driving circuit 130 may be disposed in, and/or electrically connected to, but not limited to, a portion of a first area (e.g., a left area or a right area) and a portion of a second area (e.g., the right area or the left area) of the active area AA of the display panel 110.

Herein, the gate driving circuit 130 embedded in the display panel 110 by the gate-in-panel (GIP) technology may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more example embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be implemented in the form of a touch panel outside of the display panel 110 or be integrated inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the process of manufacturing the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing configuration or a mutual-capacitance sensing configuration.

In the example where the touch sensing circuit performs touch sensing by the self-capacitance sensing configuration, the touch sensing circuit can perform touch sensing based on a capacitance between one or more touch electrode and an object such as a finger, a pen, and/or the like. According to the self-capacitance sensing configuration, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing configuration, the touch sensing circuit can perform touch sensing based on a capacitance between touch electrodes. According to the mutual-capacitance sensing configuration, a plurality of touch electrodes may be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit may be implemented in separate devices or in a single device. In one or more aspects, the touch driving circuit and the data driving circuit may be implemented in separate devices or in a single device.

The display device 100 may further include a power supply circuit configured to supply various types of power to the display driving circuit and/or the touch sensing circuit.

In some aspects, the display device 100 may be a mobile terminal such as a smart phone, a tablet, or the like, or a monitor, a television (TV), or the like. Such devices may be configured in various types, sizes, and shapes. The display device 100 according to one or more aspects of the present disclosure are not limited thereto, and may include various types, sizes, and shapes configured to display information or images. The display device 100 according to the aspects of the present disclosure may be applied to mobile devices, video phones, smart watches, watch phones, wearable devices, foldable devices, rollable devices, bendable devices, flexible devices, stretchable devices, curved devices, sliding devices, variable devices, electronic notebooks, e-books, portable multimedia players (PMP), personal digital assistants (PDA), MP3 players, mobile medical devices, desktop PCs, laptop PCs, netbook computers, workstations, navigation devices, car navigation devices, vehicle display devices, vehicle apparatuses, theater apparatuses, theater display devices, televisions, wallpaper devices, signage devices, game devices, notebook computers, monitors, cameras, camcorders, and home appliances, and the like.

In one or more aspects, the display device 100 may further include an electronic device such as a camera (e.g., an image sensor), a sensor capable of detecting an object, ambient light, and the like. For example, the sensor may be a sensor capable of detecting an object or a human body by receiving light such as infrared light, ultrasonic light, ultraviolet light or the like.

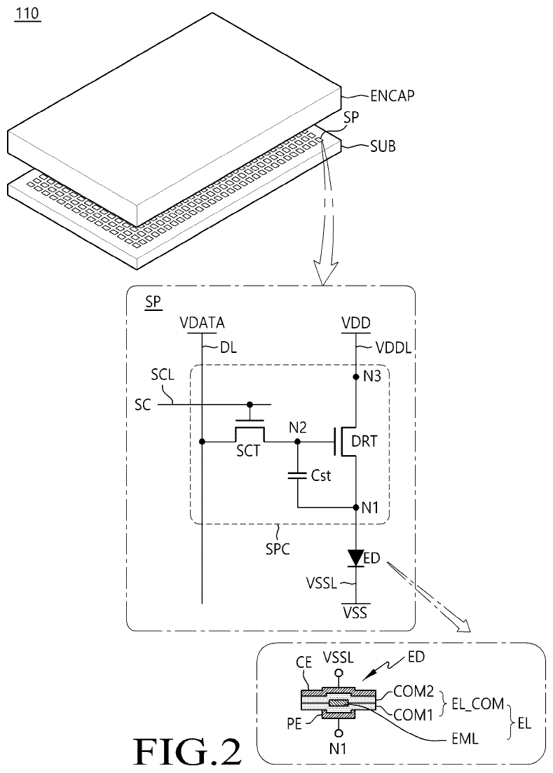

FIG. 2 illustrates an example configuration of the display panel 110 according to one or more aspects of the present disclosure. In discussions that follow for the configuration of FIG. 2, discussions for features and examples equal, substantially equal, or similar to the features and examples described with reference to FIG. 1 are omitted or briefly described for convenience of description.

Referring to FIG. 2, the display panel 110 may include a substrate SUB on which a plurality of subpixels SP are disposed, and an encapsulation layer ENCAP over the substrate SUB. The encapsulation layer ENCAP may also be referred to as an encapsulation substrate or an encapsulation stack.

Referring to FIG. 2, in an example where the display device 100 is a self-emission display device, each of the plurality of subpixels SP disposed on the substrate SUB may include a light emitting element ED and a subpixel circuit SPC for driving the light emitting element ED.

Referring to FIG. 2, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DRT for driving the light emitting element ED and a scan transistor ST configured to be turned on or turned off according to a scan signal SCT.

The driving transistor DRT can supply a driving current to the light emitting element ED.

The scan transistor SCT may be configured to control an electrical state of a corresponding node in the subpixel circuit SPC or to control the state or operation of the driving transistor DRT.

The at least one capacitor may include a storage capacitor Cst configured to maintain a certain level of voltage during a display frame or a certain period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, a common pixel driving voltage including a first common driving voltage VDD and a second common driving voltage VSS may be applied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode disposed commonly in all or some of a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions may be provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed in each subpixel SP, and the common intermediate layer EL_COM may be disposed commonly across all or some of a plurality of subpixels SP.

The emission layer EML may be disposed in each light emitting area, and the common intermediate layer EL_COM may be disposed commonly across all or some of a plurality of light emitting areas and all or some of a plurality of non-light emitting areas.

For example, the first common intermediate layer COM1 may include a hole injection layer (HIL), a hole transfer layer (HTL), and the like. The second common intermediate layer COM2 may include an electron transport layer (ETL), an electron injection layer (EIL), and the like.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE may be electrically connected to a second common driving voltage line VSSL. A second common driving voltage VSS, which is a type of common pixel driving voltage, may be applied to the common electrode CE through the second common driving voltage line VSSL. The pixel electrode PE may be electrically connected directly or indirectly (via another transistor) to a first node N1 of a corresponding driving transistor DRT of each subpixel SP. Herein, the second common driving voltage VSS may also be referred to as a “base voltage”, and the second common driving voltage line VSSL may also be referred to as a “low power supply voltage line”, a “low voltage line”, or a “base voltage line.”

Each light emitting element ED may be configured by the overlap of a corresponding pixel electrode PE, a corresponding emission layer in the intermediate layer EL, and a portion of the common electrode CE. A respective light emitting area may be formed by each light emitting element ED. For example, a respective light emitting area of each light emitting element ED may include an area where a corresponding pixel electrode PE, a corresponding emission layer in the intermediate layer EL, and a portion of the common electrode CE overlap with each other.

In some aspects, each light emitting element ED may be an organic light emitting diode (OLED), an inorganic light emitting diode (iLED), a quantum dot light emitting element (QLED), or the like. In the example where each light emitting element ED is an organic light emitting diode (OLED), the intermediate layer EL of a corresponding light emitting element ED may be a layer including an organic material.

The driving transistor DRT may be a transistor configured to supply a driving current to the light emitting element ED. The driving transistor DRT may be connected between a first common driving voltage line VDDL and the light emitting element ED.

The driving transistor DRT may include a first node N1, a second node N2, and a third node N3. The first node N1 may be electrically connected to the light emitting element ED. A data signal VDATA may be applied to the second node N2. The first common driving voltage VDD through the first common driving voltage line VDDL may be applied to the third node N3.

In the driving transistor DRT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DRT are source, gate, and drain nodes, respectively. However, aspects of the present disclosure are not limited thereto.

The scan transistor SCT included in the subpixel circuit SPC illustrated in FIG. 2 may be a switching transistor for allowing a data signal VDATA, which is an image signal, to be supplied to the second node N2, which is the gate node of the driving transistor DRT.

The scan transistor SCT can be turned on or turned off by a scan signal SC, which is a type of gate signal, carried by a scan line SCL, which is a type of gate line GL, and control an electrical connection between the second node N2 of the driving transistor DRT and a data line DL. The drain electrode or source electrode of the scan transistor SCT may be electrically connected to the data line DL. The source electrode or drain electrode of the scan transistor SCT may be electrically connected to the second node N2 of the driving transistor DRT. The gate electrode of the scan transistor SCT may be electrically connected to the scan line SCL.

The storage capacitor Cst may be electrically connected between the first node N1 and the second node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

In some aspects, the storage capacitor Cst, which may be present between the first node N1 and the second node N2 of the driving transistor DRT, may be an external capacitor intentionally configured or designed to be located outside of the driving transistor DRT, other than internal capacitors, such as parasitic capacitors (e.g., a gate-to-source capacitance Cgs, a gate-to-drain capacitance Cgd, and the like).

Each of the driving transistor DRT and the scan transistor SCT may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 2, the subpixel circuit SPC may include two transistors (2T: DRT and SCT) and one capacitor (1C: Cst) (which may be referred to as a “2T1C structure”), and in some implementations, may further include one or more transistors, and/or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitor. In further another example, the subpixel circuit SPC may have an 7T1C structure including 7 transistors and 1 capacitor.

The types and number of gate signals supplied to a subpixel SP, and/or the types and number of gate lines connected to the subpixel SP may vary depending on a structure of a corresponding subpixel circuit SPC. Further, the types and number of common pixel driving voltages supplied to a subpixel SP may vary depending on a structure of a corresponding subpixel circuit SPC.

Since circuit elements (in particular, a light emitting element ED implemented with an organic light emitting diode including an organic material) included in each subpixel SP are subject to external moisture or oxygen, an encapsulation layer ENCAP may be disposed in the display panel 110 in order to prevent external moisture or oxygen from penetrating into such circuit elements. The encapsulation layer ENCAP may be disposed in various shapes or configurations to prevent light emitting elements ED from contacting moisture or oxygen. For example, the encapsulation layer ENCAP may include two or more layers in which organic and inorganic layers are alternately stacked, but aspects of the present disclosure are not limited thereto.

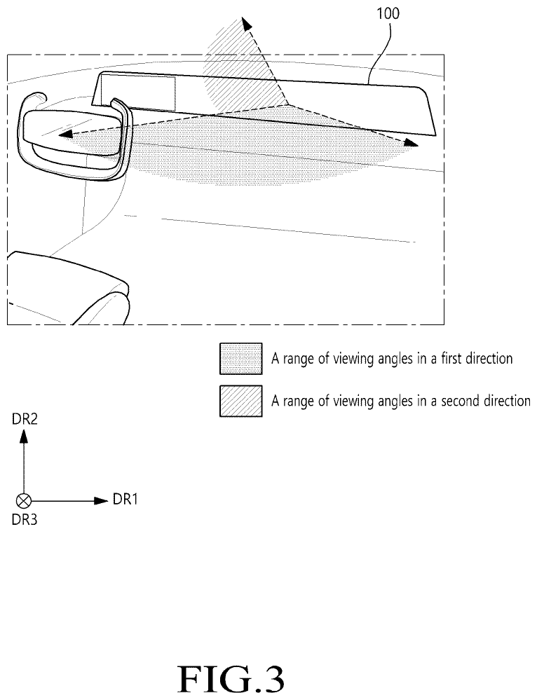

FIG. 3 illustrates an example vehicle equipped with the display device 100 according to one or more aspects of the present disclosure. In discussions that follow for the configuration of FIG. 3, discussions for features and examples equal, substantially equal, or similar to the features and examples described with reference to FIGS. 1 and 2 are omitted or briefly described for convenience of description.

Referring to FIG. 3, the display device 100 may be disposed on at least a portion of a dashboard of a vehicle. The dashboard of the vehicle may be a part disposed in front of at least one front seat (e.g., a driver's seat and/or a passenger's seat) of the vehicle. For example, configurations such as instruments, switches, and the like for operating various devices and/or systems (e.g., an air conditioner, an audio system, a navigation system, and/or the like) installed in the vehicle may be disposed in the dashboard of the vehicle.

The display device 100 may be disposed in the dashboard of the vehicle and serve as an input device and/or an output device for operating at least one or more of various functions of the vehicle. The display device 100 may provide various information related to the vehicle, for example, information related to driving of the vehicle (e.g., a current speed, a remaining amount of fuel, a driving distance, and the like), information on parts of the vehicle (e.g., damage to tires and the like), and the like.

As illustrated in FIG. 3, the display device 100 may be disposed in a portion of the dashboard corresponding to an area across the driver's seat and the passenger's seat of the vehicle. A user of the display device 100 may include a driver of the vehicle and a passenger in the passenger's seat. Both the driver and the passenger of the vehicle may use the display device 100.

In one or more aspects, the display device 100 may have a viewing angle in a first direction DR1 and a viewing angle in a second direction DR2. The first direction DR1 and the second direction DR2 may be directions that intersect, or are orthogonal to, each other. Based on the user looking at the display device 100, the first direction DR1 may be a left-right direction, a horizontal direction, or a row direction, and the second direction DR2 may be an up-down direction, a vertical direction, or a column direction.

In one or more aspects, since the driver and the passenger of the display device 100 are located in the left-right direction of the display device 100 mounted on the dashboard of the vehicle, it may be desirable for the display device 100 to have a large viewing angle in the first direction DR1, which is the horizontal direction. In one or more aspects, since images from the display device 100 can be reflected on the windshield of the vehicle located in front of the display device 100 and obstruct the driver's view, it may be desirable for the display device 100 to have a structure where a viewing angle in the second direction DR2, which is the vertical direction, can be adjusted to one or more levels.

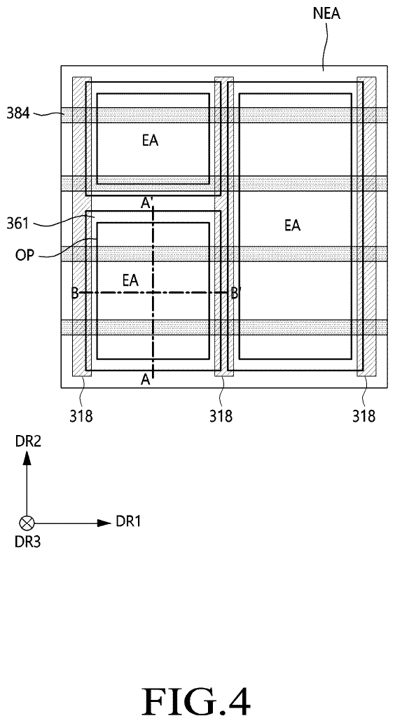

FIG. 4 is an example plan view illustrating subpixels SP disposed in the active area AA in the display device 100 according to one or more aspects of the present disclosure. In discussions that follow for the configuration of FIG. 4, discussions for features and examples equal, substantially equal, or similar to the features and examples described with reference to FIGS. 1 to 3 are omitted or briefly described for convenience of description.

Referring to FIG. 4, the display device 100 may include subpixels SP and a viewing angle adjuster including viewing angle adjustment patterns 384.

A plurality of subpixels SP may be disposed in the active area AA. A plurality of structures 318 and a plurality of viewing angle adjustment patterns 384 may be disposed in the active area AA. The plurality of structures 318 and the plurality of viewing angle adjustment patterns 384 may intersect each other.

Each of the plurality of structures 318 may be configured to be spaced apart from each other in a first direction DR1, and each of the plurality of viewing angle adjustment patterns 384 may be configured to be spaced apart from each other in a second direction DR2. Each of the plurality of structures 318 may be configured to extend in (or along) the second direction DR2, and each of the plurality of viewing angle adjustment patterns 384 may be configured to extend in (or along) the first direction DR1.

Referring to FIG. 4, a plurality of light emitting areas EA and a non-light emitting area NEA surrounding the plurality of light emitting areas EA may be disposed in the active area AA.

The plurality of light emitting areas EA may be light emitting areas emitting light of different colors. For example, one light emitting area EA may be an area emitting red light, another light emitting area EA may be an area emitting green light, and another light emitting area EA may be an area emitting blue light. In one or more aspects, FIG. 4 illustrates a structure in which three light emitting areas emitting light of different colors are disposed in the active area AA, but aspects of the present disclosure are not limited thereto. For example, four or more light emitting areas emitting light of different colors may be disposed in the active area AA.

Referring to FIG. 4, in a plan view, at least one light emitting area among the plurality of light emitting areas EA may have an area different from the remaining light emitting areas. By designing light emitting areas EA emitting light of different colors to have different areas from each other, light emitting elements disposed in the light emitting areas EA can be configured to have respective lifetimes, transmissive characteristics, and reflectivity characteristics, and thereby, the light emitting elements can produce optimal efficiency.

For example, the lifetime of a light emitting element emitting blue light may be shorter than those of light emitting elements emitting red light and green light. To compensate for this, an area of a light emitting area emitting blue light may be formed to be greater than each of respective areas of light emitting areas emitting red light and green light.

In one or more aspects, each of one or more light emitting areas EA disposed in the active area AA of the display device 100 may include a first light emitting area and at least one second light emitting area.

The first light emitting area may be an area corresponding to an area where a first electrode 361, an emission layer, and a second electrode are sequentially stacked and overlap with each other. The first light emitting area may be an area where some of light emitted from the emission layer is directed outside of the display panel 110 or the display device 100 in an open area OP. The second light emitting area may be an area where some of the light emitted from the emission layer is reflected from an inclined surface and redirected outside of the display panel 110 or the display device 100. For example, the second light emitting area may be an area where some of the light emitted from the emission layer is reflected from a portion of the first electrode 361 disposed on a corresponding inclined surface of at least one of the structures 318 and then redirected outside of the display panel 110 or the display device 100.

Referring to FIG. 4, the plurality of structures 318 may be configured to be spaced apart in the first direction DR1 and extend in the second direction DR2. In one or more aspects, the plurality of structures 318 may be disposed in left and right sides or portions of each light emitting area EA, respectively. However, a structure 318 may be not disposed in upper and lower portions of each light emitting area EA. As the plurality of structures 318 are disposed in positions of each light emitting area EA, respective inclined surfaces of the structures 318 may be configured to be spaced apart in the first direction DR1 and extend in the second direction DR2. For example, each light emitting area EA may include a first light emitting area and a second light emitting area configured to be spaced apart in the first direction DR1 and extend in the second direction DR2. In this implementation, the second light emitting area may be disposed non-parallel to the first direction DR1.

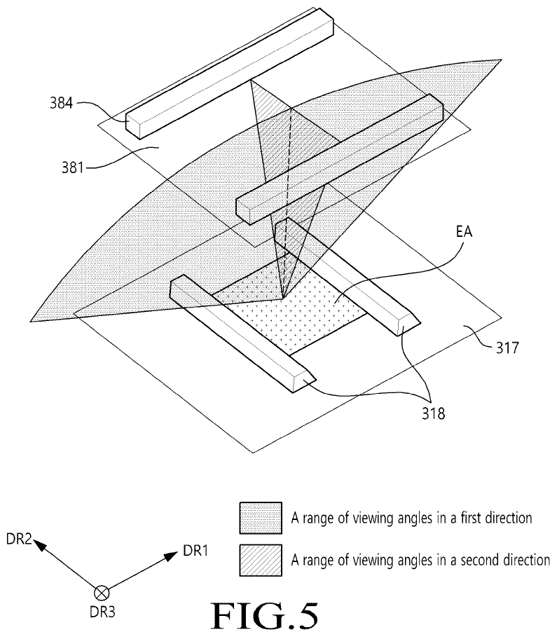

FIG. 5 is a perspective view illustrating an example portion of the display device 100 according to one or more aspects of the present disclosure. In discussions that follow for the configuration of FIG. 5, discussions for features and examples equal, substantially equal, or similar to the features and examples described with reference to FIGS. 1 to 4 are omitted or briefly described for convenience of description.

In or more aspects, the display device 100 illustrated in FIG. 5 may include a viewing angle adjustment film, which is a viewing angle adjuster, on a light emitting area EA. The viewing angle adjustment film may include a plurality of viewing angle adjustment patterns 384 on a first base layer 381.

Referring to FIG. 5, a plurality of structures 318 and the plurality of viewing angle adjustment patterns 384 may be configured to intersect each other. The plurality of structures 318 may be configured to be spaced apart in a first direction DR1 and extend in a second direction DR2, and the plurality of viewing angle adjustment patterns 384 may be configured to be spaced apart in the second direction DR2 and extend in the first direction DR1.

Referring to FIG. 5, for example, some light directed in the first direction DR1 among light emitted in a light emitting area EA may produce a wide range of viewing angles. In another example, some light directed in the second direction DR2 among the light emitted in the light emitting area EA may be redirected by the viewing angle adjustment patterns 384, and thereby, can produce a narrow range of viewing angles. A viewing angle or a range of viewing angles in the first direction DR1 may be greater than a viewing angle or a range of viewing angles in the second direction DR2.

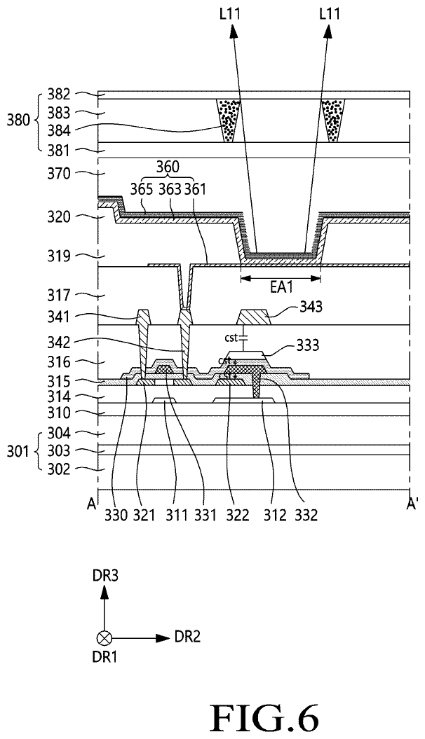

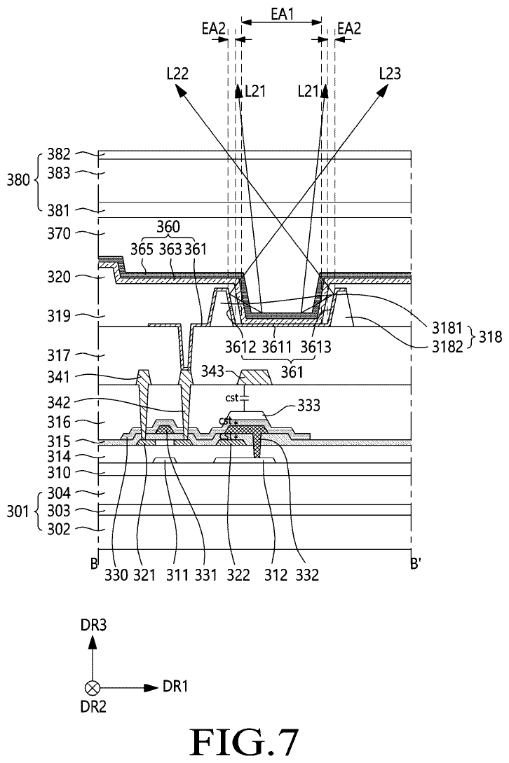

FIG. 6 is an example cross-sectional view taken along line A-A′ of FIG. 4, and FIG. 7 is an example cross-sectional view taken along line B-B′ of FIG. 4. In discussions that follow for the configurations of FIGS. 6 and 7, discussions for features and examples equal, substantially equal, or similar to the features and examples described with reference to FIGS. 1 to 5 are omitted or briefly described for convenience of description.

Referring to FIGS. 6 and 7, in one or more aspects, the display device 100 may include at least one transistor TR disposed over a substrate 301, a light emitting element 360 electrically connected to the transistor TR, and a viewing angle adjustment film 380 disposed on the light emitting element 360.

The transistor TR may include an active layer 321, a gate electrode 331, a source electrode 342, and a drain electrode 341.

The light emitting element 360 may include a first electrode 361, an emission layer 363, and a second electrode 365. For example, the first electrode 361 may be a pixel electrode, and the second electrode 365 may be a common electrode. For example, the pixel electrode may be an anode electrode, and the common electrode may be a cathode electrode. In another example, the pixel electrode may be a cathode electrode, and the common electrode may be an anode electrode. Hereinafter, for convenience of explanation, discussions are provided on examples where the pixel electrode is an anode electrode and the common electrode is a cathode electrode, but aspects of the present disclosure are not limited thereto.

Referring to FIGS. 6 and 7, the substrate 301 may include a first substrate 302 and a second substrate 304, and an intermediate layer 303 may be disposed between the first substrate 302 and the second substrate 304. For example, the intermediate layer 303 may be an inorganic layer, and can serve to prevent the penetration of moisture. However, the structure of the substrate 301 according to one or more aspects of the present disclosure is not limited to this. For example, the substrate 400 may have a single layer structure different from the structure of the substrate 301 illustrated in FIGS. 6 and 7.

A first buffer layer 310 may be disposed on the substrate 301. The first buffer layer 310 may be a single layer or include multiple layers.

A light shield 311 may be disposed on the first buffer layer 310.

A second buffer layer 314 may be disposed on the light shield 311.

An active layer 321 and a first storage capacitor electrode 322 may be disposed on the second buffer layer 314. In one or more aspects, the active layer 321 may include a channel region, and the channel region may overlap with at least a portion of the light shield 311 and overlap with the gate electrode 331.

The remaining area excluding the channel region of the active layer 321 may be a region in which the active layer 321 is modified to become conductive (which may be referred to as a conductivity-enabled region). The active layer 321 may include an oxide semiconductor material.

The first storage capacitor electrode 322 may be disposed in the same layer as the active layer 321. The first storage capacitor electrode 322 may be in a conductivity-enabled state where an oxide semiconductor material is modified to become conductive, but aspects of the present disclosure are not limited thereto.

A gate insulating layer 315 may be disposed on the active layer 321 and the first storage capacitor electrode 322.

A gate electrode 331 and a second storage capacitor electrode 332 may be disposed on the gate insulating layer 315.

The gate electrode 331 may overlap with the channel region of the active layer 321, and the second storage capacitor electrode 332 may overlap with the first storage capacitor electrode 322. The second storage capacitor electrode 332 may be electrically connected to a metal layer 312 disposed in the same layer as the light shield 311, but aspects of the present disclosure are not limited thereto.

An interlayer insulating layer 330 may be disposed on the gate electrode 331 and the second storage capacitor electrode 332.

A third storage capacitor electrode 333 may be disposed on the interlayer insulating layer 330. The third storage capacitor electrode 333 may overlap with the second storage capacitor electrode 332.

A protective layer 316 may be disposed on the third storage capacitor electrode 333. The protective layer 316 may include an organic insulating material or an inorganic insulating material.

A source electrode 342, a drain electrode 341, and a fourth storage capacitor electrode 343 may be disposed on the protective layer 316.

The source electrode 342 and the drain electrode 341 may be configured to be spaced apart from each other and be electrically connected to the conductivity-enabled region of the active layer 321.

The fourth storage capacitor electrode 343 may overlap with the third storage capacitor electrode 333.

Referring to FIGS. 6 and 7, the first to fourth storage capacitor electrodes (322, 332, 333, and 343) may be configured to overlap with each other, and may form a storage capacitor Cst.

Referring to FIGS. 6 and 7, an insulating layer 317 may be disposed on the source electrode 342, the drain electrode 341, and the fourth storage capacitor electrode 343.

The insulating layer 317 may serve to planarize the surface of the substrate 301. The insulating layer 317 may include an organic insulating material or an inorganic insulating material, but aspects of the present disclosure are not limited thereto.

Referring to FIGS. 6 and 7, the insulating layer 317 may include one hole in an area overlapping with a portion of the upper surface of the source electrode 342 of the transistor.

Referring to FIG. 7, structures 318 may be disposed on the insulating layer 317. The structures 318 may be configured to be spaced apart in the first direction DR1 and extend in the second direction DR2. The structures 318 may include an organic insulating material or an inorganic insulating material, but aspects of the present disclosure are not limited thereto.

Referring to FIGS. 6 and 7, a light emitting element 360 including a first electrode 361, an emission layer 363, and a second electrode 365 may be disposed on the insulating layer 317.

Referring to FIGS. 6 and 7, the first electrode 361 may be disposed on the insulating layer 317 and the structures 318.

The first electrode 361 may include a reflective material. For example, the first electrode 361 may include at least one of aluminum (Al), neodymium (Nd), nickel (Ni), titanium (Ti), tantalum (Ta), copper (Cu), silver (Ag), and an aluminum alloy, but aspects of the present disclosure are not limited thereto. In one or more aspects, the first electrode 361 may be electrically connected to the source electrode 342 of the transistor TR through a contact hole in the insulating layer 317. In one or more aspects, the first electrode 361 may be electrically connected to the drain electrode 341 of the transistor TR through a contact hole in the insulating layer 317.

Referring to FIGS. 6 and 7, a bank 319 may be disposed on the first electrode 361. The bank 319 may be disposed on the first electrode 361 and include an open area to expose a portion of the first electrode 361.

Referring to FIGS. 6 and 7, a spacer 320 may be disposed on a portion of the upper surface of the bank 319. The spacer 320 may be disposed in a non-light emitting area NEA.

Referring to FIGS. 6 and 7, the emission layer 363 may be disposed over the substrate 301 over which the bank 319 is disposed. The emission layer 363 may be disposed on the first electrode 361 in the open area of the bank 319. The emission layer 363 may be disposed in each subpixel SP or be disposed commonly in all or some of a plurality of subpixels SP.

Referring to FIGS. 6 and 7, the second electrode 365 may be disposed over the substrate 301 over which the emission layer 363 is disposed.

The second electrode 365 may include a conductive material capable of transmitting or semi-transmitting light. For example, the second electrode 365 may include at least one kind of transparent conductive oxide, such as indium tin oxide (ITO), indium zinc oxide (IZO), indium tin zinc oxide (ITZO), zinc oxide, tin oxide, and the like, or include a semi-transmissive metal, such as magnesium (Mg), silver (Ag), or an alloy of Mg and Ag. In an example where the second electrode 365 includes a semi-transmissive metal, a thickness of the second electrode 365 may be smaller than that of the first electrode 361.

Referring to FIGS. 6 and 7, an encapsulation layer 370 may be disposed on the light emitting element 360. The encapsulation layer 370 may be disposed on the second electrode 365 of the light emitting element 360.

The encapsulation layer 370 may be a layer configured to prevent moisture or oxygen from penetrating into the light emitting element 360 disposed under the encapsulation layer 370. The encapsulation layer 370 may prevent moisture or oxygen from penetrating into the emission layer 363. For example, the encapsulation layer 370 may be a single layer or include multiple layers.

The encapsulation layer 370 may include a first encapsulation layer, a second encapsulation layer, and a third encapsulation layer. The first encapsulation layer and the third encapsulation layer may be inorganic layers including an inorganic insulating material, and the second encapsulation layer may be an organic layer including an organic insulating material. As the second encapsulation layer includes an organic material, the second encapsulation layer can also serve as a planarization layer.

Referring to FIGS. 6 and 7, a viewing angle adjustment film 380 may be disposed on the encapsulation layer 370. The viewing angle adjustment film 380 may be a viewing angle adjuster configured to adjust viewing angles of light emitted from the emission layer 363.

The viewing angle adjustment film 380 may include a first base layer 381, a second base layer 382, at least one transmissive area 383, and viewing angle adjustment patterns 384.

The first base layer 381 may be disposed on the encapsulation layer 370. The first base layer 381 may include a material with high light transmittance.

A resin layer including the transmissive area 383 and the viewing angle adjustment patterns 384 may be disposed on the first base layer 381. The resin layer may be a transparent resin layer. The resin layer may include a transparent insulating resin capable of enabling the transmissive area 383 to transmit light incident from the light emitting area. For example, the resin layer may include an acrylic resin.

Referring to FIG. 6, the viewing angle adjustment patterns 384 may be configured to be spaced apart in the second direction DR2 and extend in the first direction DR1. Although the viewing angle adjustment patterns 384 are disposed over the encapsulation layer 370 as shown in FIG. 4, the viewing angle adjustment patterns 384 may be not shown in FIG. 7. In this way, the viewing angle adjustment patterns 384 may be disposed in a direction intersecting, or orthogonal to, structures 318, and be not disposed parallel to the structures 318.

The viewing angle adjustment patterns 384 may be formed by a printing process or a patterning process. For example, the printing process may be performed by a roll printing, an imprinting, a screen printing, a gravure printing, a gravure-offset printing, or a flexographic printing. For example, the printing process may include a process of forming a mask pattern material on the first base layer, and an etching process of selectively etching the mask pattern material. The etching process may be, for example, a wet etching process, a dry etching process, or a laser scribing process.

The viewing angle adjustment patterns 384 may include a light absorbing or light shielding material. For example, the viewing angle adjustment patterns 384 may include a colored organic material such as black carbon and the like, but aspects of the present disclosure are not limited thereto.

A width of the transmissive area 383 may be greater than a width of each of the viewing angle adjustment patterns 384.

The second base layer 382 may be disposed on the resin layer. The second base layer 382 may be substantially the same as the first base layer 381. Therefore, discussions for the second base layer 382 are omitted.

Referring to FIGS. 6 and 7, in one or more aspects, the display device 100 may include a light emitting area EA. The light emitting area EA may include a first light emitting area EA1 and at least one second light emitting area EA2 formed in areas different from each other according to directions (e.g., the first direction DR1 and the second direction DR2) where light emitted from the emission layer 363 is directed.

Referring to FIG. 6, the light emitting area EA may include a first light emitting area EA1 corresponding to the open area of the bank 319 in the second direction DR2. The first light emitting area EA1 may be an area corresponding to an area where the first electrode 361, the emission layer 363, and the second electrode 365 are sequentially stacked and overlap with each other.

Referring to FIG. 6, some light L11 among light emitted from the emission layer 363 in the first light emitting area EA1 may be redirected by the viewing angle adjustment patterns 384 disposed over the emission layer 363 and caused to move outside of (or exit) the display panel 110 or the display device 100. In this way, some light directed in the second direction DR2 among the light emitted from the emission layer 363 in the first light emitting area EA1 may be redirected by the viewing angle adjustment patterns 384, and thereby, can produce a narrow range of viewing angles.

Referring to FIG. 7, the light emitting area EA may include the first light emitting area EA1 corresponding to the open area of the bank 319 in the first direction DR1 and second light emitting areas EA2 corresponding to respective inclined surfaces of the structures 318. The structures 318 may include a first structure 3181 and a second structure 3182.

The first light emitting area EA1 may be an area corresponding to an area where a lower portion 3611 of the first electrode 361, the emission layer 363, and the second electrode 365 are sequentially stacked and overlap with each other. The second light emitting areas EA2 may be respective areas that correspond to a first inclined surface 3612 of the first electrode 361 disposed on an inclined surface of the first structure 3181 and a second inclined surface 3613 of the first electrode 361 disposed on an inclined surface of the second structure 3182.

Referring to FIG. 7, some light L21 among light emitted from the emission layer 363 in the first light emitting area EA1 may be directed outside of the display panel 110 or the display device 100 without being reflected. Some light (L22 and L23) directed to the first and second structures (3181 and 3182) among the light emitted from the emission layer 363 in the first light emitting area EA1 may be reflected from the first and second inclined surfaces (3612 and 3613) of the first electrode 361, and then redirected outside of the display panel 110 or the display device 100. In this way, light directed in the third direction DR3 among the light emitted from the emission layer 363 in the first light emitting area EA1 may be directed outside of the display panel 110 or the display device 100 without being reflected. Further, light directed to sides in the first direction DR1 among the light emitted from the emission layer 363 in the first light emitting area EA1 may be reflected in the second light emitting areas EA2 and then redirected outside of the display panel 110 or the display device 100. Therefore, some light directed or redirected in the first direction DR1 among light emitted in the first light emitting area EA1 and the second light emitting areas EA2 can produce improved light extraction efficiency, improved viewing angle luminance in the first direction DR1, and a wide range of viewing angles.

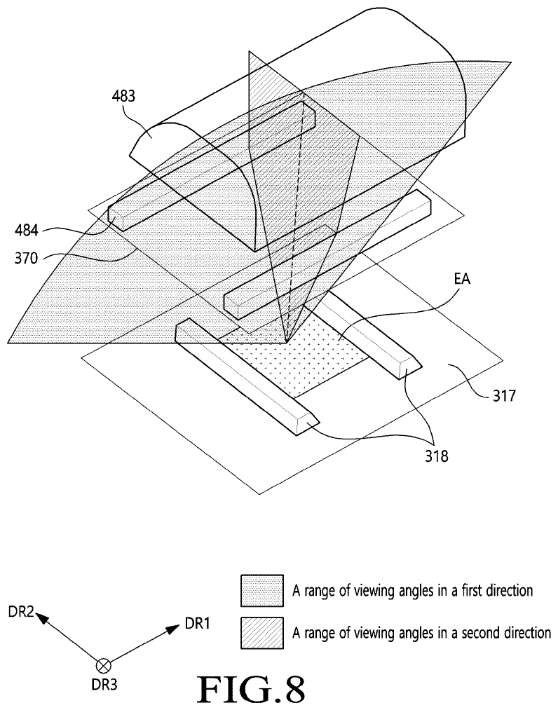

FIG. 8 is a perspective view illustrating an example portion of the display device 100 according to one or more aspects of the present disclosure. In discussions that follow for the configuration of FIG. 8, discussions for features and examples equal, substantially equal, or similar to the features and examples described with reference to FIGS. 1 to 7 are omitted or briefly described for convenience of description.

In or more aspects, the display device 100 illustrated in FIG. 8 may include a panel-embedded viewing angle adjustment structure, which is a viewing angle adjuster, on a light emitting area EA. The panel-embedded viewing angle adjustment structure may include viewing angle adjustment patterns 484 and a viewing angle adjustment lens 483 on the encapsulation layer 370.

Referring to FIG. 8, a plurality of structures 318 and a plurality of viewing angle adjustment patterns 484 may be configured to intersect each other. The plurality of structures 318 may be configured to be spaced apart in a first direction DR1 and extend in a second direction DR2, and the plurality of viewing angle adjustment patterns 484 may be configured to be spaced apart in the second direction DR2 and extend in the first direction DR1. In one or more aspects, the viewing angle adjustment lens 483 may be configured to extend in the first direction DR1. For example, a length of the viewing angle adjustment lens 483 in the first direction DR1 may be greater than a length of the viewing angle adjustment lens 483 in the second direction DR2.

Referring to FIG. 8, for example, some light directed in the first direction DR1 among light emitted in the light emitting area EA may produce a wide range of viewing angles. In another example, some light directed in the second direction DR2 among the light emitted in the light emitting area EA may be redirected by the viewing angle adjustment patterns 484, and thereafter, pass through the viewing angle adjustment lens 483 and exit the display panel 110 or the display device 100. Accordingly, some light directed in the second direction DR2 may produce a narrow range of viewing angles. Thus, a viewing angle or a range of viewing angles in the first direction DR1 may be greater than a viewing angle or a range of viewing angles in the second direction DR2.

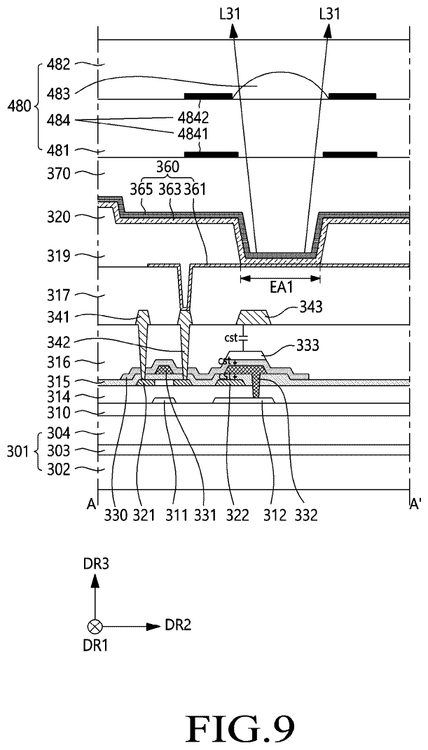

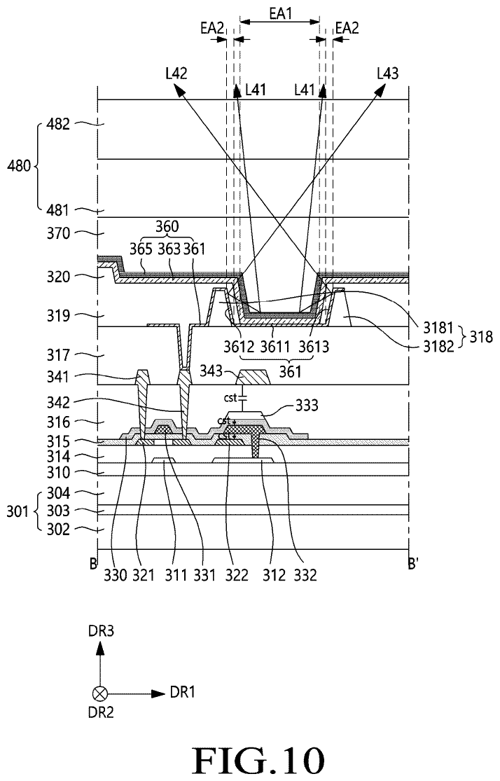

FIG. 9 is another example cross-sectional view taken along line A-A′ of FIG. 4, and FIG. 10 is another example cross-sectional view taken along line B-B′ of FIG. 4. In discussions that follow for the configurations of FIGS. 9 and 10, discussions for features and examples equal, substantially equal, or similar to the features and examples described with reference to FIGS. 1 to 8 are omitted or briefly described for convenience of description.

Referring to FIGS. 9 and 10, in one or more aspects, the display device 100 may include at least one transistor TR disposed over a substrate 301, a light emitting element 360 electrically connected to the transistor TR, and a panel-embedded viewing angle adjustment structure 480 disposed on the light emitting element 360.

The respective remaining configurations illustrated in FIGS. 9 and 10 except for the panel-embedded viewing angle adjustment structure 480 may be substantially the same as the respective configurations illustrated in FIGS. 6 and 7, respectively, and therefore, discussions for these configurations are omitted for convenience of description.

Referring to FIGS. 9 and 10, the panel-embedded viewing angle adjustment structure 480 may be disposed on an encapsulation layer 370. The panel-embedded viewing angle adjustment structure 480 may be a viewing angle adjuster configured to adjust a viewing angle of light emitted from an emission layer 363.

The panel-embedded viewing angle adjustment structure 480 may include a first planarization layer 481, a second planarization layer 482, a viewing angle adjustment lens 483, and viewing angle adjustment patterns 484.

The viewing angle adjustment patterns 484 may be disposed on the encapsulation layer 370. The viewing angle adjustment patterns 484 may be configured to overlap with a non-light emitting area NEA. The viewing angle adjustment patterns 484 may be configured to overlap with a bank 319. The viewing angle adjustment patterns 484 may be disposed outside of the viewing angle adjustment lens 483.

The viewing angle adjustment patterns 484 may include a plurality of layers. The viewing angle adjustment patterns 484 may include a first viewing angle adjustment pattern 4841 and a second viewing angle adjustment pattern 4842. The first viewing angle adjustment pattern 4841 and the second viewing angle adjustment pattern 4842 may be configured to overlap with each other. The second viewing angle adjustment pattern 4842 and the viewing angle adjustment lens 483 may be disposed in the same layer.

The viewing angle adjustment patterns 484 may include a light absorbing or light shielding material. For example, the viewing angle adjustment patterns 484 may include a black matrix. In one or more aspects, the viewing angle adjustment patterns 484 may include a touch electrode. For example, at least one of the first viewing angle adjustment pattern 4841 and the second viewing angle adjustment pattern 4842 may include a light absorbing material or a light shielding material. For example, at least one of the first viewing angle adjustment pattern 4841 and the second viewing angle adjustment pattern 4842 may include a touch electrode.

Referring to FIG. 9, the viewing angle adjustment patterns 484 may be configured to be spaced apart in the second direction DR2 and extend in the first direction DR1. Although the viewing angle adjustment patterns 484 are disposed over the encapsulation layer 370 as shown in FIG. 4, the viewing angle adjustment patterns 484 may be not shown in FIG. 10. In this way, the viewing angle adjustment patterns 484 may be disposed in a direction intersecting, or orthogonal to, structures 318, and be not disposed parallel to the structures 318.

The first planarization layer 481 may be disposed on the encapsulation layer 370. The first planarization layer 481 may be disposed between the first viewing angle adjustment pattern 4841 and the second viewing angle adjustment pattern 4842. The first planarization layer 481 may include a transparent insulating material. The first planarization layer 481 can remove a step caused by the first viewing angle adjustment pattern 4841 and prevent damage to the first viewing angle adjustment pattern 4841 due to external moisture and impact.

The viewing angle adjustment lens 483 may be disposed on the first planarization layer 481. The viewing angle adjustment lens 483 may be configured to overlap with an open area of the bank 319. The viewing angle adjustment lens 483 may be configured to overlap with a first light emitting area EA1. For example, light L31 emitted from the emission layer 363 may pass through the viewing angle adjustment lens 483 and exit the display panel 110 or the display device.

The second planarization layer 482 may be disposed on the first planarization layer 481, the viewing angle adjustment lens 483, and the second viewing angle adjustment pattern 4842. The second planarization layer 482 may be substantially the same as the first planarization layer 481. Therefore, discussions for the second planarization layer 482 are omitted.

Referring to FIGS. 9 and 10, in one or more aspects, the display device 100 may include a light emitting area EA. The light emitting area EA may include a first light emitting area EA1 and at least one second light emitting area EA2 formed in areas different from each other according to directions (e.g., the first direction DR1 and the second direction DR2) where light emitted from the emission layer 363 is directed.

Referring to FIG. 9, the light emitting area EA may include a first light emitting area EA1 corresponding to the open area of the bank 319 in the second direction DR2. The first light emitting area EA1 may be an area corresponding to an area where a first electrode 361, the emission layer 363, and a second electrode 365 are sequentially stacked and overlap with each other.

Referring to FIG. 9, some light L31 among light emitted from the emission layer 363 in the first light emitting area EA1 may be redirected by the viewing angle adjustment patterns 484 disposed over the emission layer 363 and caused to move outside of the display panel 110 or the display device 100. In this way, some light directed in the second direction DR2 among the light emitted from the emission layer 363 in the first light emitting area EA1 may be redirected by the viewing angle adjustment patterns 484, and pathways of light exiting the display panel 110 or the display device 100 may be adjusted through the viewing angle adjustment lens 483. Thus, some light directed in the second direction DR2 can produce a narrow range of viewing angles.

Referring to FIG. 10, the light emitting area EA may include the first light emitting area EA1 corresponding to the open area of the bank 319 in the first direction DR1 and second light emitting areas EA2 corresponding to respective inclined surfaces of the structures 318. The structures 318 may include a first structure 3181 and a second structure 3182.

The first light emitting area EA1 may be an area corresponding to an area where a lower portion 3611 of the first electrode 361, the emission layer 363, and the second electrode 365 are sequentially stacked and overlap with each other. The second light emitting areas EA2 may be respective areas that correspond to a first inclined surface 3612 of the first electrode 361 disposed on an inclined surface of the first structure 3181 and a second inclined surface 3613 of the first electrode 361 disposed on an inclined surface of the second structure 3182.

Referring to FIG. 10, some light L41 among light emitted from the emission layer 363 in the first light emitting area EA1 may be directed outside of the display panel 110 or the display device 100 without being reflected. Some light (L42 and L43) directed to the first and second structures (3181 and 3182) among the light emitted from the emission layer 363 in the first light emitting area EA1 may be reflected from the first and second inclined surfaces (3612 and 3613) of the first electrode 361, and redirected outside of the display panel 110 or the display device 100. In this way, light directed in the third direction DR3 among the light emitted from the emission layer 363 in the first light emitting area EA1 may be directed outside of the display panel 110 or the display device 100 without being reflected. Further, light directed to sides in the first direction DR1 among the light emitted from the emission layer 363 in the first light emitting area EA1 may be reflected in the second light emitting areas EA2 and redirected outside of the display panel 110 or the display device 100. Therefore, some light directed or redirected in the first direction DR1 among light emitted in the first light emitting area EA1 and the second light emitting areas EA2 can produce improved light extraction efficiency, improved viewing angle luminance in the first direction DR1, and a wide range of viewing angles.

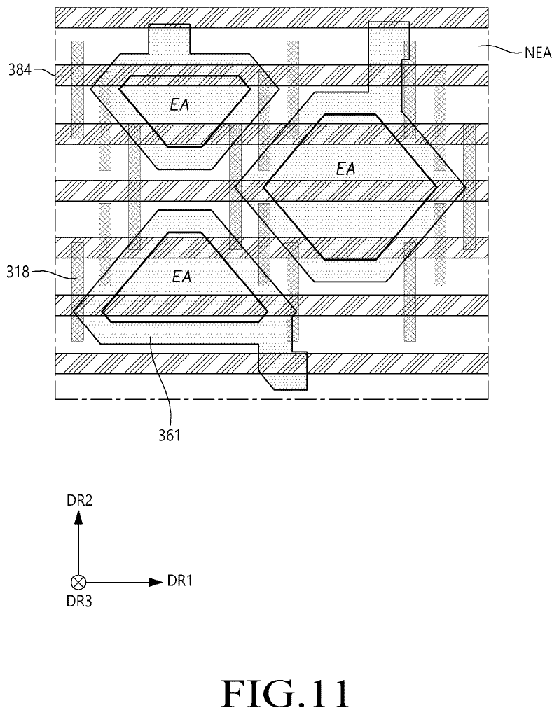

FIG. 11 is an example plan view illustrating subpixels SP disposed in the active area AA in the display device 100 according to one or more aspects of the present disclosure. In discussions that follow for the configuration of FIG. 11, discussions for features and examples equal, substantially equal, or similar to the features and examples described with reference to FIGS. 1 to 10 are omitted or briefly described for convenience of description.

Referring to FIG. 11, the display device 100 may include subpixels SP and a viewing angle adjuster including viewing angle adjustment patterns 384.

A plurality of subpixels SP may be disposed in the active area AA. A plurality of structures 318 and a plurality of viewing angle adjustment patterns 384 may be disposed in the active area AA. The plurality of structures 318 and the plurality of viewing angle adjustment patterns 384 may intersect each other.

Each of the plurality of structures 318 may be configured to be spaced apart from each other in a first direction DR1, and each of the plurality of viewing angle adjustment patterns 384 may be configured to be spaced apart from each other in a second direction DR2. Each of the plurality of structures 318 may be configured to extend in the second direction DR2, and each of the plurality of viewing angle adjustment patterns 384 may be configured to extend in the first direction DR1. A plurality of structures 318 may be configured to be spaced apart from each other along the periphery or edge of an open area of a bank.

Referring to FIG. 11, a plurality of light emitting areas EA and a non-light emitting area NEA surrounding the plurality of light emitting areas EA may be disposed in the active area AA. The plurality of light emitting areas EA may have shapes different from each other in a plan view. For example, the light emitting areas EA may have shapes corresponding to a circular, elliptical, or polygonal shape, or a combination of one or more of the circular, elliptical, and polygonal shapes. The polygonal shape may be, for example, a triangle, a square, a pentagon, or a hexagon, or a combination of one or more of the triangle, the square, the pentagon, and the hexagon. The light emitting areas EA may correspond to open areas of the bank.

Referring to FIG. 11, the light emitting areas EA may have a triangular shape and a hexagonal shape, and the light emitting areas EA may have shapes corresponding to open areas of the bank. A plurality of structures 318 may be configured to be spaced apart from each other along the periphery or edge of an open area of the bank. Since a plurality of structures 318 are configured to be spaced apart along the periphery or edge of an open area, the plurality of structures 318 can be disposed close to a corresponding light emitting area EA (e.g., a corresponding first light emitting area EA1). Since a plurality of structures 318 are disposed close to a corresponding light emitting area EA, inclined surface of the plurality of structures 318 can be disposed close to a corresponding light emitting area EA. In this way, since light directed laterally in a light emitting area EA can be reflected by a first electrode 361 disposed on inclined surfaces of a plurality of structures 318, and redirected outside of the display panel 110 or the display device 100, viewing angle luminance in the first direction DR1 can be improved.

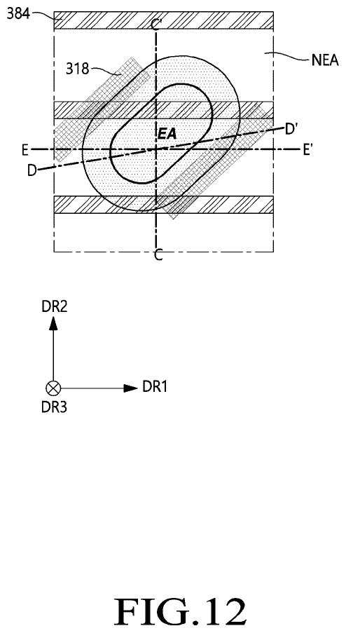

FIG. 12 is an example plan view illustrating a subpixel SP disposed in the active area AA in the display device 100 according to one or more aspects of the present disclosure. In discussions that follow for the configuration of FIG. 12, discussions for features and examples equal, substantially equal, or similar to the features and examples described with reference to FIGS. 1 to 11 are omitted or briefly described for convenience of description.

Referring to FIG. 12, a light emitting area EA may be disposed in a direction with an angle to a first direction DR1 or a second direction DR2. In this implementation, a plurality of structures 318 may be configured to be spaced apart from each other in the first direction and extend in the direction with the angle to the first direction DR1 or the second direction DR2. For example, the plurality of structures 318 may be disposed in the same direction as the light emitting area EA. In one or more aspects, viewing angle adjustment patterns 384 may be configured to be spaced apart from each other in the second direction DR2 and extend in the first direction DR1.

Since the plurality of structures 318 are disposed in the same direction as the light emitting area EA, the number of structures 318 disposed can be minimized.

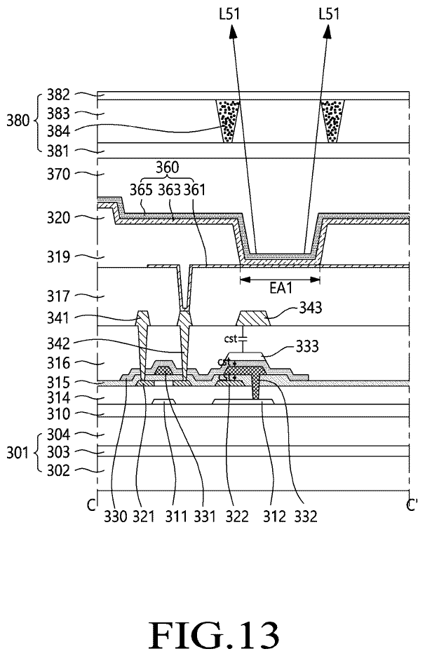

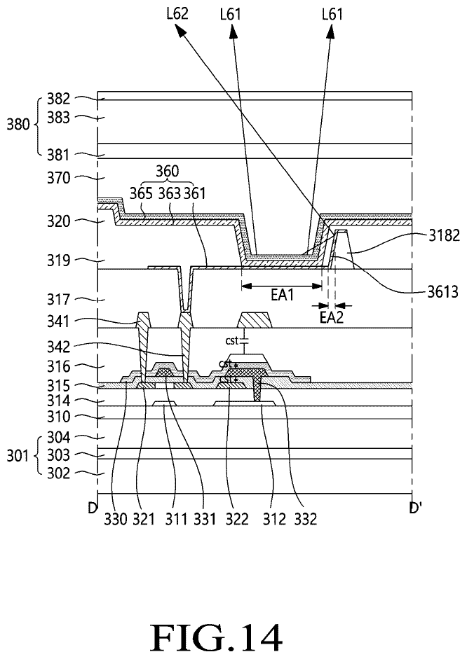

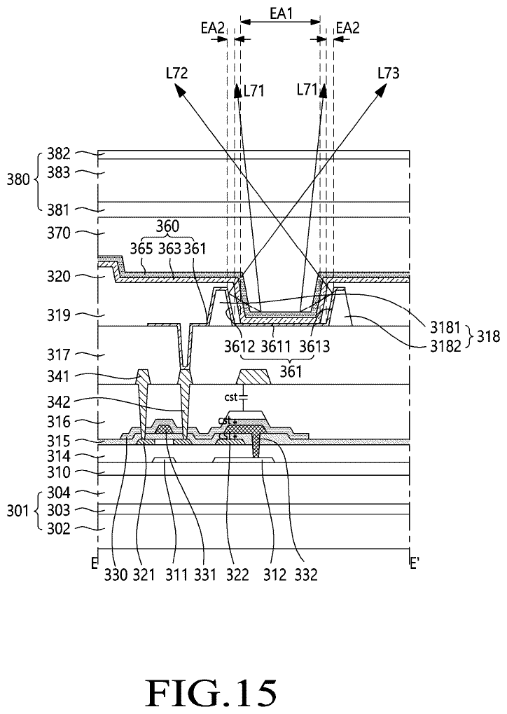

FIG. 13 is an example cross-sectional view taken along line C-C′ of FIG. 12 according to one or more aspects of the present disclosure. FIG. 14 is an example cross-sectional view taken along line D-D′ of FIG. 12 according to one or more aspects of the present disclosure. FIG. 15 is an example cross-sectional view taken along line E-E′ of FIG. 12 according to one or more aspects of the present disclosure. In discussions that follow for the configurations of FIGS. 13 to 15, discussions for features and examples equal, substantially equal, or similar to the features and examples described with reference to FIGS. 1 to 12 are omitted or briefly described for convenience of description.

The configuration illustrated in FIG. 13 may be substantially the same as the configuration illustrated in FIG. 6, and the configuration illustrated in FIG. 15 may be substantially the same as the configuration illustrated in FIG. 7. Thus, discussions for the configuration of FIG. 13 substantially the same as the configuration of FIG. 6, and the configuration of FIG. 15 substantially the same as the configuration of FIG. 7 are omitted.

Referring to FIG. 13, some light L51 directed in the second direction DR2 among light emitted from an emission layer 363 in a first light emitting area EA1 may be redirected by the viewing angle adjustment patterns 384, and thereby, can produce a narrow range of viewing angles.

Referring to FIG. 14, some light L61 directed in the first direction DR1 among the light emitted from the emission layer 363 in the first light emitting area EA1 may be directed outside of the display panel 110 or the display device 100 without being reflected. Further, light L62 directed to a right side in the first direction DR1 among the light emitted from the emission layer 363 in the first light emitting area EA1 may be reflected in a second light emitting area EA2 disposed in a second structure 3182 and redirected outside of the display panel 110 or the display device 100. Therefore, among light emitted in the first light emitting area EA1 and the second light emitting area EA2, some light directed or redirected in a direction with an angle to the first direction DR1 or the second direction DR2 can produce improved light extraction efficiency, improved viewing angle luminance, and a wide range of viewing angles, compared to some light directed in the second direction DR2.

Referring to FIG. 15, some light L71 directed in the first direction DR1 among the light emitted from the emission layer 363 in the first light emitting area EA1 may be directed outside of the display panel 110 or the display device 100 without being reflected. Further, some light (L72, L73) directed to sides in the first direction DR1 among the light emitted from the emission layer 363 in the first light emitting area EA1 may be reflected in second light emitting areas EA2 disposed in first and second structures (3181 and 3182) and redirected outside of the display panel 110 or the display device 100. Therefore, some light directed or redirected in the first direction DR1 among light emitted in the first light emitting area EA1 and the second light emitting areas EA2 can produce improved light extraction efficiency, improved viewing angle luminance in the first direction DR1, and a wide range of viewing angles, compared to some light directed in the second direction DR2 and in a direction with an angle to the first direction DR1 or the second direction DR2.

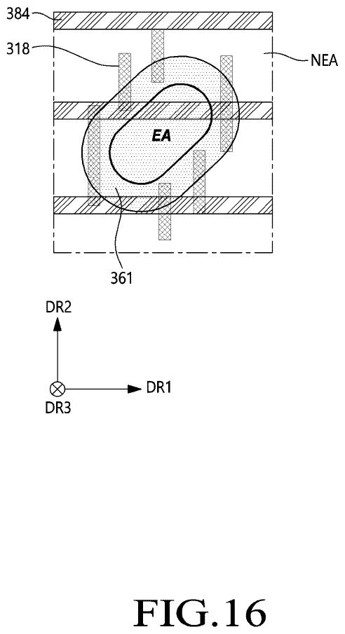

FIGS. 16 to 18 are example plan views illustrating subpixels SP disposed in the active area AA in the display device 100 according to one or more aspects of the present disclosure. In discussions that follow for the configurations of FIGS. 16 to 18, discussions for features and examples equal, substantially equal, or similar to the features and examples described with reference to FIGS. 1 to 15 are omitted or briefly described for convenience of description.

Referring to FIG. 16, a light emitting area EA may be disposed in a direction with an angle to a first direction DR1 or a second direction DR2. The light emitting area EA may have a shape corresponding to a shape of an open area of a bank.

A plurality of structures 318 may be configured to be spaced apart in a first direction DR1 and extend in a second direction DR2. The plurality of structures 318 may be configured to be spaced apart from each other along the periphery or edge of the open area of the bank. Since the plurality of structures 318 are configured to be spaced apart along the periphery or edge of the open area, the plurality of structures 318 can be disposed close to the light emitting area EA. Since the plurality of structures 318 are disposed close to the light emitting area EA, inclined surface of the plurality of structures 318 can be disposed close to the light emitting area EA. In this way, light directed laterally in the light emitting area EA may be reflected by a first electrode 361 disposed on inclined surfaces of the plurality of structures 318 and be redirected outside of the display panel 110 or the display device 100, and thereby, can produce improved viewing angle luminance in the first direction DR1.

In one or more aspects, FIG. 16 illustrates that one or more of the structures 318 disposed adjacent to the light emitting area EA overlap with the first electrode 361, but aspects of the present disclosure are not limited thereto. For example, the first electrode 361 may be not disposed in one or more portions located outside of the light emitting area EA among corresponding portions of at least one structure 318 disposed adjacent to the light emitting area EA. The first electrode 361 may be patterned so that the first electrode 361 cannot be disposed in the one or more portions located outside of the light emitting area EA among the portions of the at least one structure 318 disposed adjacent to the light emitting area EA. For example, the structures 318 and the first electrode 361 may be disposed so that viewing angle luminance cannot be increased undesirably in the second direction DR2.

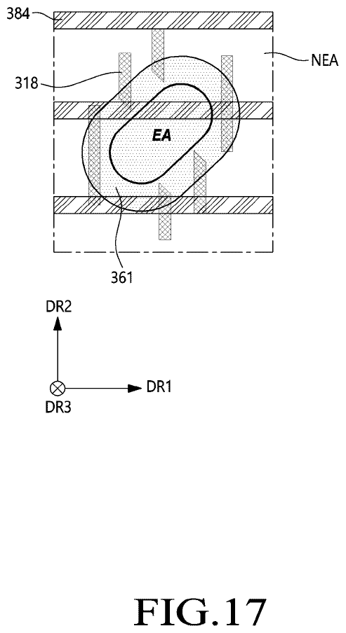

The configuration illustrated in FIG. 17 except for a shape of one end of each of one or more of structures 318 may be substantially the same as the configuration of FIG. 16. Thus, discussions for the configuration of FIG. 17 substantially the same as the configuration of FIG. 16 are omitted.

Referring to FIG. 17, one end or edge of each of one or more of structures 318 disposed adjacent to a light emitting area EA may protrude toward the light emitting area EA. For example, one end or edge of each of the one or more structures 318 may protrude in a triangle shape toward the light emitting area EA. One end or edge of each of the one or more structures 318 may have a triangle shape with a slope at a location adjacent to an outer edge of the light emitting area EA and protrude toward the light emitting area EA. In this way, the shape of one end or edge of each of the one or more structures 318 may be configured to protrude in a triangle shape toward the light emitting area EA so that viewing angle luminance cannot be increased undesirably in the second direction DR2.

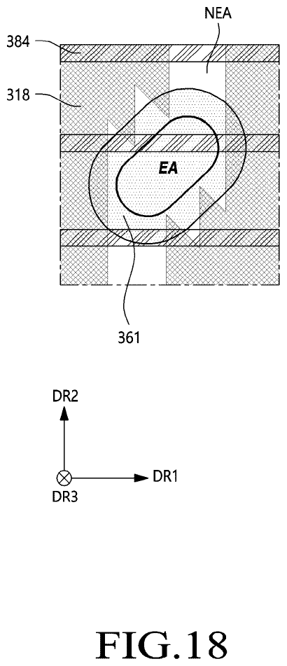

Referring to FIG. 18, a light emitting area EA may be disposed in a direction with an angle to a first direction DR1 or a second direction DR2. The light emitting area EA may have a shape correspond to a shape of an open area of a bank.

A plurality of structures 318 may be configured to be spaced apart from each other with the light emitting area EA interposed therebetween. A respective portion of each of the structures 318 may be disposed in an area where a virtual line extending in a second direction DR2 and a non-open area of a bank overlap with each other. The portion of each of the structures 318 may protrude toward the open area (e.g., a light emitting area EA or EA1) of the bank. In one or more examples, the structures 318 do not overlap the open area of the bank. One end or edge of each of the structures 318 may have a triangle shape protruding toward the light emitting area EA. One end or edge of each of the structures 318 may have a triangle shape with a slope at a location adjacent to an outer edge of the light emitting area EA and protrude toward the light emitting area EA. In this way, the shape of one end or edge of each of the structures 318 may be configured to protrude in a triangle shape toward the light emitting area EA so that viewing angle luminance cannot be increased undesirably in the second direction DR2.

In some examples, a plurality of viewing angle adjustment patterns 384 may be substituted by a plurality of viewing angle adjustment patterns 484, and vice versa.

In some examples, a light emitting area EA may refer to a first light emitting area EA1. For example, a light emitting area EA shown in FIGS. 4, 5, 8, 11, 12, and 16-18 may refer to a first light emitting area EA1.

Further, while not illustrated in FIGS. 5 and 8 for brevity, in one or more examples, a gap (or a first non-light emitting area) may be disposed between a light emitting area EA (corresponding to a first light emitting area EA1) and each of the structures 318. In reference to FIGS. 7, 10, 14 and 15, a gap between a first light emitting area EA1 and a second light emitting area EA2 may be a first non-light emitting area.

Various examples and aspects of the present disclosure are described below. These are provided as examples, and do not limit the scope of the present disclosure.

In connection with FIGS. 1 to 18, in one or more aspects, the display device 100 may be, may be included in, or may include, a foldable device. A foldable device may refer to, or may be, a foldable display device, a rollable device, a bendable device, a flexible device, a stretchable device, a curved device, a sliding device, or a variable device, and vice versa. The display device 100 according to one or more aspects of the present disclosure may be, or may be included in, a mobile terminal (e.g., a smart phone, a video phone, a smart watch, a watch phone, a wearable device, a tablet, an electronic notebook, a notebook computer, a netbook computer, an e-book, a portable multimedia player (PMP), a personal digital assistant (PDA), an MPEG-1 Audio Layer 3 (MP3) player, a mobile medical device, a laptop, or the like), a desktop personal computer (PC), a workstation, a navigation device, a car navigation device, a vehicle display device, a vehicle apparatus, a theater apparatus, a theater display device, a television, a wallpaper device, a signage device, a gaming device, a monitor, a camera, a sensor, a camcorder, or a home appliance, or the like. The display device 100 according to one or more aspects of the present disclosure are not limited to the foregoing example devices. The display device 100 according to one or more aspects of the present disclosure may be made in various types, sizes, and shapes that are configured to display information and/or images.

In connection with FIGS. 1 to 18, in one or more aspects, when the display device 100 is a foldable device, a foldable area may be formed around a folding axis. In an example, the foldable area may overlap a portion of the display area DA and/or a portion of the non-display area NDA. The foldable area may be an area that is folded with a predefined curvature when the foldable device is folded in at least one scheme among inner folding and outer folding. An area other than the foldable area may be a non-foldable area. A foldable area may include one or more foldable areas. Moreover, when the display device 100 is the foldable device, in some examples, the display device may further include a hinge structure for folding a display panel or the like, and a casing for supporting and accommodating the display panel or the like. In one or more examples, when the display device 100 is the foldable device, the substrate of the display device may be a multilayer substrate, and the substrate may be flexible.

In connection with FIGS. 1 to 18, in one or more aspects, the substrate 301 of the display device 100 may serve to support and protect constituent elements of the display device 100 that are disposed above the substrate 301. The substrate 301 is a component for supporting various constituent elements included in the display device 100 and may be made of one or more insulating materials. The substrate 301 may be a multilayer substrate (e.g., a triple-layer substrate), including, for example, the first substrate 302, the second substrate 304, and the intermediate layer 303. The intermediate layer 303 may be disposed between the first substrate 302 and the second substrate 304. The substrate, being multilayer, can minimize moisture penetration from the outside. In another example, the substrate 301 may be disposed as a single layer.

The first substrate 302 may have rigidity and flexibility. Among the components of the substrate 301, the first substrate 302 may be configured to substantially support the constituent elements of the display device 100. For example, the first substrate 302 may be a flexible substrate made of polyimide (PI). However, the present disclosure is not limited thereto.

The intermediate layer 303 may be disposed on an entire surface of the first substrate 302. The intermediate layer 303 may be made of an inorganic insulating material. For example, the intermediate layer 303 may be configured as a single layer or multilayer made of silicon nitride (SiNx) or silicon oxide (SiOx). However, the present disclosure is not limited thereto.

The second substrate 304 may be disposed on the intermediate layer 303. The second substrate 304 may have rigidity and flexibility. Among the components of the substrate 301, the second substrate 304, together with the first substrate 302, may be configured to substantially support the constituent elements of the display device 100. For example, the second substrate 304 may be a flexible substrate made of polyimide (PI). However, the present disclosure is not limited thereto.

In connection with FIGS. 1 to 18, in one or more aspects, light from an emission layer 363 may be converted to various color light through a separate color conversion layer and a color filter. In some examples, a color filter may be disposed on the encapsulation layer 370 or on one or more layers thereof. Further, the color filter may be disposed to overlap the emission layer 363 or a light emitting area (e.g., EA or EA1). A color filter may include one or more color filters.

In connection with FIGS. 1 to 18, in one or more aspects, the display device 100 may include a touch sensor disposed on the encapsulation layer 370. The touch sensor may include one or more touch electrodes. In some examples, the color filter (or a portion thereof) may be disposed on the touch sensor. In some examples, the color filter may overlap the touch sensor. In some examples, the color filter may overlap the light emitting area and the touch sensor. In some examples, a portion of the color filter may overlap the light emitting area, and another portion of the color filter may overlap the touch sensor. In some examples, multiple color filters may be disposed on the touch sensor.

Various examples and aspects of the present disclosure are described further below. These are provided as examples, and do not limit the scope of the present disclosure.

According to one or more aspects of the present disclosure, a display device may comprise: a substrate; an insulating layer disposed on the substrate; a plurality of structures that are spaced apart from each other, are disposed on the insulating layer, and include an insulating material; a pixel electrode that is disposed on the insulating layer and on at least one or more parts of the plurality of structures; and a plurality of viewing angle adjustment patterns that are spaced apart from each other and are disposed above the plurality of structures. The plurality of viewing angle adjustment patterns may extend in a first direction, and the plurality of structures may extend in a second direction different from the first direction.

In one or more examples, the plurality of viewing angle adjustment patterns may be configured to adjust a viewing angle of light emitted from an emission layer disposed on the pixel electrode.

In one or more examples, the plurality of viewing angle adjustment patterns may be configured to adjust in one direction a viewing angle of light emitted from an emission layer; the plurality of structures may be configured to adjust in another direction a viewing angle of light emitted from the emission layer; and the another direction may be different from the one direction.

In one or more examples, the plurality of viewing angle adjustment patterns may be configured to reduce in one direction a viewing angle of light emitted from an emission layer; the plurality of structures may be configured to widen in another direction a viewing angle of light emitted from the emission layer; the another direction may be different from the one direction; and the viewing angle in the another direction may be greater than the viewing angle in the one direction.

In one or more examples, a viewing angle associated with the first direction may be greater than a viewing angle associated with the second direction.

In one or more examples, the second direction may be perpendicular to the first direction.

In one or more examples, the second direction may be oblique to the first direction. For example, the second direction is a direction that is not parallel to and is not perpendicular to the first direction. For example, the second direction and the first direction form an acute angle.

In one or more examples, the first and second directions may be directions that intersect each other or that are orthogonal to each other.

In one or more examples, a length of each of the plurality of viewing angle adjustment patterns in the first direction may be greater than a width of a respective one of the plurality of viewing angle adjustment patterns. For example, when a length is in a direction DR1, the width is in another direction that is perpendicular to the direction DR1. The another direction may lie on a plane defined by the directions DR1 and DR2.

In one or more examples, the plurality of viewing angle adjustment patterns may be spaced apart from each other in a direction different from the first direction. For example, if the first direction is a direction DR1, then the direction different from the first direction may be a direction DR2.

In one or more examples, the plurality of viewing angle adjustment patterns may include a light absorbing material or a light shielding material.

In one or more examples, the display device may comprise: an encapsulation layer, at least one or more portions of which are disposed above the plurality of structures; and a viewing angle adjustment film disposed on the encapsulation layer. In one or more examples, the viewing angle adjustment film may comprise: a first base layer disposed on the encapsulation layer; at least one transmissive area disposed on the first base layer; the plurality of viewing angle adjustment patterns disposed on the first base layer; and a second base layer disposed on the at least one transmissive area and the plurality of viewing angle adjustment patterns.

In one or more examples, a width of the at least one transmissive area may be greater than a width of each of the plurality of viewing angle adjustment patterns.

In one or more examples, the display device may comprise: an encapsulation layer, at least one or more portions of which are disposed above the plurality of structures; and a panel-embedded viewing angle adjustment structure disposed on the encapsulation layer.

In one or more examples, the plurality of viewing angle adjustment patterns may comprise: a first viewing angle adjustment pattern; and a second viewing angle adjustment pattern. In one or more examples, the panel-embedded viewing angle adjustment structure may comprise: a first planarization layer disposed on the encapsulation layer; the first viewing angle adjustment pattern disposed on the encapsulation layer; the second viewing angle adjustment pattern disposed on the first planarization layer; and a viewing angle adjustment lens disposed on the first planarization layer.

In one or more examples, the viewing angle adjustment lens may overlap a light emitting area; and the viewing angle adjustment lens may be configured to cause light emitted from an emission layer to pass through the viewing angle adjustment lens and exit the display device.

In one or more examples, a length of the viewing angle adjustment lens in the first direction may be greater than a width of the viewing angle adjustment lens.

In one or more examples, the plurality of viewing angle adjustment patterns may overlap a non-light emitting area and may be disposed outside of the viewing angle adjustment lens.

In one or more examples, the second viewing angle adjustment pattern and the viewing angle adjustment lens may be disposed in a same layer.

In one or more examples, the first viewing angle adjustment pattern and the second viewing angle adjustment pattern may overlap each other.

In one or more examples, at least one of the first viewing angle adjustment pattern and the second viewing angle adjustment pattern may include a touch electrode.

In one or more examples, the plurality of viewing angle adjustment patterns may include a touch electrode.

In one or more examples, a length of each of the plurality of structures in the second direction may be greater than a width of a respective one of the plurality of structures. For example, when a length is in the second direction, the width is in another direction that is perpendicular to the second direction. The second direction and the another direction may lie on a plane defined by directions DR1 and DR2. In an example, the second direction is the direction DR2. In an example, the second direction is not the direction DR2.

In one or more examples, the plurality of structures may be spaced apart from each other in a direction different from the second direction. For example, if the second direction is a direction DR2, then the direction different from the second direction may be a direction DR1. For example, if the second direction is a direction DR2, then the direction different from the second direction may be a direction that is oblique to the second direction.

In one or more examples, the pixel electrode, disposed on the at least one or more parts of the plurality of structures, may be disposed on at least one or more inclined surfaces of the plurality of structures; the pixel electrode disposed on the at least one or more inclined surfaces may be configured to reflect at least some light among light emitted from an emission layer and to redirect the at least some light toward an outside of the display device; and at least some other light among the light emitted from the emission layer may be directed toward the outside of the display device without being reflected by the pixel electrode disposed on the at least one or more inclined surfaces.

In one or more examples, the display device may comprise: a bank that is disposed on the pixel electrode and includes an open area to expose a portion of the pixel electrode. In one or more examples, a light emitting area may comprise a first light emitting area and a second light emitting area; the first light emitting area may correspond to the open area; the second light emitting area may correspond to one or more areas of the pixel electrode disposed on at least one or more inclined surfaces of the plurality of structures; the second light emitting area may be adjacent to the first light emitting area and partially surround the first light emitting area; and a non-light emitting area may surround the light emitting area.

In one or more examples, the plurality of viewing angle adjustment patterns may overlap at least one or more portions of the second light emitting area and do not cover at least one or more portions of the first light emitting area.

In one or more examples, the first light emitting area may be disposed in a same direction as the second direction in which the plurality of structures extend; and the second direction may be oblique to the first direction.

In one or more examples, at least some light among light emitted from an emission layer in the first light emitting area may be reflected in the second light emitting area and redirected toward an outside of the display device; and at least some other light among the light emitted from the emission layer in the first light emitting area may be directed toward the outside of the display device without being reflected in the second light emitting area.

In one or more examples, at least one edge of each of the plurality of structures may have a shape with a slope at a location adjacent to an outer edge of the first light emitting area and protrude toward the first light emitting area.

According to one or more aspects of the present disclosure, a display device may comprise: a light emitting area; one or more structures that are disposed adjacent to the light emitting area, and are configured to adjust a viewing angle of light emitted from an emission layer; and one or more viewing angle adjustment patterns that are disposed above the one or more structures and are configured to adjust a viewing angle of light emitted from the emission layer.

In one or more examples, the one or more structures may be configured to widen in a first direction a first viewing angle of at least some light emitted from the emission layer; the one or more viewing angle adjustment patterns may be configured to reduce in a second direction a second viewing angle of at least some other light emitted from the emission layer; the first direction may be different from the second direction; and the first viewing angle may be greater than the second viewing angle.

According to one or more aspects of the present disclosure, a display device may comprise: a light emitting area; one or more structures that are disposed adjacent to the light emitting area, only partially surround the light emitting area, and extend in a direction; and a pixel electrode that is disposed at the light emitting area and on at least one or more inclined surfaces of the one or more structures. In one or more examples, the pixel electrode disposed on the at least one or more inclined surfaces may be configured to adjust a viewing angle of light emitted from an emission layer.

In one or more examples, the display device may further comprise: one or more viewing angle adjustment patterns that are disposed above the one or more structures and are configured to adjust a viewing angle of light emitted from the emission layer. In one or more examples, the one or more viewing angle adjustment patterns may be disposed on one layer or on multiple different layers.

In one or more examples, in a plan view, the one or more structures may be disposed at two sides of the light emitting area and are not disposed at two other sides of the light emitting area.

In one or more examples, the one or more structures may be two or more structures, and the two or more structures may be separate and discrete islands extending in the direction (in a plan view). In one or more examples, the two or more structures may be individual components in a plan view.

According to one or more aspects of the present disclosure, a display device may comprise: a light emitting area; an emission layer that is disposed at the light emitting area; and one or more viewing angle adjustment patterns that are disposed above the emission layer and are configured to adjust a viewing angle of light emitted from the emission layer.

In one or more examples, the one or more viewing angle adjustment patterns may adjust the viewing angle of the light by adjusting the light (e.g., directing, redirecting, absorbing, blocking, expanding, spreading, scattering, altering, controlling, manipulating, passing, reflecting, or guiding the light).

In one or more examples, the one or more viewing angle adjustment patterns may be disposed at at least two sides of the light emitting area in a plan view.

In one or more examples, the one or more viewing angle adjustment patterns are not disposed at two other sides of the light emitting area in a plan view.

In one or more examples, the one or more viewing angle adjustment patterns may be configured to adjust the viewing angle of the light along one direction, and the viewing angle along the one direction (e.g., DR2) is less than another viewing angle of the light along another direction (e.g., DR1).

In one or more examples, the one or more viewing angle adjustment patterns include a light absorbing material or a light shielding material.

In one or more examples, the display device may further comprise: a second light emitting area; a second emission layer that is disposed at the second light emitting area; and one or more second viewing angle adjustment patterns that are disposed above the second emission layer and are configured to adjust a viewing angle of light emitted from the second emission layer. In one or more examples, the one or more second viewing angle adjustment patterns may be disposed at at least two sides of the second light emitting area in a plan view; and the light emitting area is greater than the second light emitting area.

According to one or more aspects of the present disclosure, a display device may be provided that includes structures in one direction and viewing angle adjustment patterns, and thereby, is capable of improving light extraction efficiency.

According to one or more aspects of the present disclosure, a display device may be provided that includes structures in one direction and viewing angle adjustment patterns, and thereby, is capable of adjusting a viewing angle according to a viewing direction and improving luminance.

According to one or more aspects of the present disclosure, a display device may be provided that is capable of being driven with low power by improving light extraction efficiency, adjusting a viewing angle according to a viewing direction, and improving luminance.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention. The scope of protection of the present disclosure should be construed based on the following claims, and all technical features within the scope of equivalents thereof should be construed as being included within the scope of the present disclosure.

What is claimed is:

1. A display device, comprising:
a substrate;
an insulating layer disposed on the substrate;
a plurality of structures that are spaced apart from each other, are disposed on the insulating layer, and include an insulating material;
a pixel electrode that is disposed on the insulating layer and on at least one or more parts of the plurality of structures; and
a plurality of viewing angle adjustment patterns that are spaced apart from each other and are disposed above the plurality of structures,
wherein:
the plurality of viewing angle adjustment patterns extend in a first direction; and
the plurality of structures extend in a second direction different from the first direction.

2. The display device of claim 1, wherein the plurality of viewing angle adjustment patterns are configured to adjust a viewing angle of light emitted from an emission layer disposed on the pixel electrode.

3. The display device of claim 1, wherein:
the plurality of viewing angle adjustment patterns are configured to adjust in one direction a viewing angle of light emitted from an emission layer;
the plurality of structures are configured to adjust in another direction a viewing angle of light emitted from the emission layer; and
the another direction is different from the one direction.

4. The display device of claim 1, wherein:
the plurality of viewing angle adjustment patterns are configured to reduce in one direction a viewing angle of light emitted from an emission layer;
the plurality of structures are configured to widen in another direction a viewing angle of light emitted from the emission layer;
the another direction is different from the one direction; and
the viewing angle in the another direction is greater than the viewing angle in the one direction.

5. The display device of claim 1, wherein a viewing angle associated with the first direction is greater than a viewing angle associated with the second direction.

6. The display device of claim 1, wherein the second direction is perpendicular to the first direction.

7. The display device of claim 1, wherein the second direction is oblique to the first direction.

8. The display device of claim 1, wherein the first and second directions are directions that intersect each other or that are orthogonal to each other.

9. The display device of claim 1, wherein:
a length of each of the plurality of viewing angle adjustment patterns in the first direction is greater than a width of a respective one of the plurality of viewing angle adjustment patterns; and
the plurality of viewing angle adjustment patterns are spaced apart from each other in a direction different from the first direction.

10. The display device of claim 1, wherein the plurality of viewing angle adjustment patterns include a light absorbing material or a light shielding material.

11. The display device of claim 1, comprising:
an encapsulation layer, at least one or more portions of which are disposed above the plurality of structures; and
a viewing angle adjustment film disposed on the encapsulation layer,
wherein the viewing angle adjustment film comprises:
a first base layer disposed on the encapsulation layer;
at least one transmissive area disposed on the first base layer;
the plurality of viewing angle adjustment patterns disposed on the first base layer; and
a second base layer disposed on the at least one transmissive area and the plurality of viewing angle adjustment patterns.

12. The display device of claim 11, wherein a width of the at least one transmissive area is greater than a width of each of the plurality of viewing angle adjustment patterns.

13. The display device of claim 1, comprising:
an encapsulation layer, at least one or more portions of which are disposed above the plurality of structures; and
a panel-embedded viewing angle adjustment structure disposed on the encapsulation layer.

14. The display device of claim 13,
wherein the plurality of viewing angle adjustment patterns comprise:
a first viewing angle adjustment pattern; and
a second viewing angle adjustment pattern, and
wherein the panel-embedded viewing angle adjustment structure comprises:
a first planarization layer disposed on the encapsulation layer;
the first viewing angle adjustment pattern disposed on the encapsulation layer;
the second viewing angle adjustment pattern disposed on the first planarization layer; and
a viewing angle adjustment lens disposed on the first planarization layer.

15. The display device of claim 14, wherein:
the viewing angle adjustment lens overlaps a light emitting area; and
the viewing angle adjustment lens is configured to cause light emitted from an emission layer to pass through the viewing angle adjustment lens and exit the display device.

16. The display device of claim 14, wherein a length of the viewing angle adjustment lens in the first direction is greater than a width of the viewing angle adjustment lens.

17. The display device of claim 14, wherein the plurality of viewing angle adjustment patterns overlap a non-light emitting area and are disposed outside of the viewing angle adjustment lens.

18. The display device of claim 14, wherein the second viewing angle adjustment pattern and the viewing angle adjustment lens are disposed in a same layer.

19. The display device of claim 14, wherein the first viewing angle adjustment pattern and the second viewing angle adjustment pattern overlap each other.

20. The display device of claim 14, wherein at least one of the first viewing angle adjustment pattern and the second viewing angle adjustment pattern includes a touch electrode.

21. The display device of claim 1, wherein the plurality of viewing angle adjustment patterns includes a touch electrode.

22. The display device of claim 1, wherein:
a length of each of the plurality of structures in the second direction is greater than a width of a respective one of the plurality of structures; and
the plurality of structures are spaced apart from each other in a direction different from the second direction.

23. The display device of claim 1, wherein:
the pixel electrode, disposed on the at least one or more parts of the plurality of structures, is disposed on at least one or more inclined surfaces of the plurality of structures;
the pixel electrode disposed on the at least one or more inclined surfaces is configured to reflect at least some light among light emitted from an emission layer and to redirect the at least some light toward an outside of the display device; and
at least some other light among the light emitted from the emission layer is for being directed toward the outside of the display device without being reflected by the pixel electrode disposed on the at least one or more inclined surfaces.

24. The display device of claim 1, comprising:
a bank that is disposed on the pixel electrode and includes an open area to expose a portion of the pixel electrode,
wherein:
a light emitting area comprises a first light emitting area and a second light emitting area;
the first light emitting area corresponds to the open area;
the second light emitting area corresponds to one or more areas of the pixel electrode disposed on at least one or more inclined surfaces of the plurality of structures;
the second light emitting area is adjacent to the first light emitting area and partially surrounds the first light emitting area; and
a non-light emitting area surrounds the light emitting area.

25. The display device of claim 24, wherein the plurality of viewing angle adjustment patterns overlap at least one or more portions of the second light emitting area and do not cover at least one or more portions of the first light emitting area.

26. The display device of claim 24, wherein:
the first light emitting area is disposed in a same direction as the second direction in which the plurality of structures extend; and
the second direction is oblique to the first direction.

27. The display device of claim 24, wherein:
at least some light among light emitted from an emission layer in the first light emitting area is for being reflected in the second light emitting area and redirected toward an outside of the display device; and
at least some other light among the light emitted from the emission layer in the first light emitting area is for being directed toward the outside of the display device without being reflected in the second light emitting area.

28. The display device of claim 24, wherein at least one edge of each of the plurality of structures has a shape with a slope at a location adjacent to an outer edge of the first light emitting area and protrudes toward the first light emitting area.

29. A display device, comprising:
a light emitting area;
one or more structures that are disposed adjacent to the light emitting area, and are configured to adjust a viewing angle of light emitted from an emission layer; and
one or more viewing angle adjustment patterns that are disposed above the one or more structures and are configured to adjust a viewing angle of light emitted from the emission layer.

30. The display device of claim 29, wherein:
the one or more structures are configured to widen in a first direction a first viewing angle of at least some light emitted from the emission layer;
the one or more viewing angle adjustment patterns are configured to reduce in a second direction a second viewing angle of at least some other light emitted from the emission layer;
the first direction is different from the second direction; and
the first viewing angle is greater than the second viewing angle.

31. A display device, comprising:
a light emitting area;
one or more structures that are disposed adjacent to the light emitting area, only partially surround the light emitting area, and extend in a direction; and
a pixel electrode that is disposed at the light emitting area and on at least one or more inclined surfaces of the one or more structures,
wherein the pixel electrode disposed on the at least one or more inclined surfaces is configured to adjust a viewing angle of light emitted from an emission layer.

32. The display device of claim 31, further comprising:
one or more viewing angle adjustment patterns that are disposed above the one or more structures and are configured to adjust a viewing angle of light emitted from the emission layer,
wherein the one or more viewing angle adjustment patterns are disposed on one layer or on multiple different layers.

33. The display device of claim 31, wherein in a plan view, the one or more structures are disposed at two sides of the light emitting area and are not disposed at two other sides of the light emitting area.

34. The display device of claim 31, wherein the one or more structures are two or more structures; and
the two or more structures are separate and discrete islands extending in the direction.

35. A display device, comprising:
a light emitting area;
an emission layer that is disposed at the light emitting area; and
one or more viewing angle adjustment patterns that are disposed above the emission layer and are configured to adjust a viewing angle of light emitted from the emission layer.

36. The display device of claim 35, wherein the one or more viewing angle adjustment patterns are disposed at at least two sides of the light emitting area in a plan view.

37. The display device of claim 36, wherein the one or more viewing angle adjustment patterns are not disposed at two other sides of the light emitting area in a plan view.

38. The display device of claim 35, wherein:
the one or more viewing angle adjustment patterns are configured to adjust the viewing angle of the light along one direction; and
the viewing angle along the one direction is less than another viewing angle of the light along another direction.

39. The display device of claim 35, wherein the one or more viewing angle adjustment patterns include a light absorbing material or a light shielding material.

40. The display device of claim 35, further comprising:
a second light emitting area;
a second emission layer that is disposed at the second light emitting area; and
one or more second viewing angle adjustment patterns that are disposed above the second emission layer and are configured to adjust a viewing angle of light emitted from the second emission layer,
wherein:
the one or more second viewing angle adjustment patterns are disposed at at least two sides of the second light emitting area in a plan view; and
the light emitting area is greater than the second light emitting area.
